(19) United States
(12) Patent Application Publication
(10) Pub. No.: US 2025/0120266 A1
(43) Pub. Date: Apr. 10, 2025

(54) DISPLAY SUBSTRATE AND DISPLAY DEVICE

(71) Applicants: Chengdu BOE Optoelectronics Technology Co., Ltd., Chengdu (Sichuan) (CN); BOE TECHNOLOGY GROUP CO., LTD., Beijing (CN)

(72) Inventors: Tiaomei ZHANG, Beijing (CN); Gukhwan SONG, Beijing (CN); Jianpeng WU, Beijing (CN); Quanyong GU, Beijing (CN); Hong YI, Beijing (CN); Zhengkun LI, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/565,813

(22) PCT Filed: May 31, 2022
(86) PCT No.: PCT/CN2022/096323

§ 371 Date: Nov. 30, 2023

(51) Int. Cl. H10K 59/131; H10K 59/121; H10K 59/126; H10K 102/00

(52) U.S. Cl. CPC H10K 59/131; H10K 59/1213; H10K 59/126; H10K 2102/361

(57) ABSTRACT

A display substrate and a display device are provided. The display substrate includes a base substrate and a plurality of pixel circuits, the plurality of pixel circuits are arranged on the base substrate in an array, the plurality of pixel circuits include a plurality of active patterns, each of the plurality of active patterns extends along a first direction, the plurality of active patterns are arranged along a second direction, adjacent active patterns are spaced apart from each other in the second direction, and at least one of the plurality of active patterns comprises at least one disconnection position to form a plurality of active sub-patterns independent of each other.

### TECHNICAL FIELD

At least one embodiment of the present disclosure relates to a display substrate and a display device.

### BACKGROUND

At present, technology on the active-matrix organic light-emitting diode (AMOLED) flexible screen is becoming more and more mature. The active-matrix AMOLED flexible screen has a high development prospect for the characteristics of bendability, high contrast, low power consumption, etc. With the continuous development of display technology, the optimization of the display effect has become an inevitable trend, and some display products adopt a disconnected active pattern design to improve the uniformity of display devices and reduce the impact on pixel process such as electrostatic discharge, etc.

### SUMMARY

At least one embodiment of the present disclosure provides a display substrate and a display device.

Embodiments of the present disclosure provide a display substrate, including: a base substrate; and a plurality of pixel circuits, the plurality of pixel circuits are arranged on the base substrate in an array, the plurality of pixel circuits include a plurality of active patterns, each of the plurality of active patterns extends along a first direction, the plurality of active patterns are arranged along a second direction, adjacent active patterns are spaced apart from each other in the second direction, and at least one of the plurality of active patterns includes at least one disconnection position to form a plurality of active sub-patterns independent of each other.

For example, according to embodiments of the present disclosure, two adjacent active sub-patterns are connected through a same connection portion at the disconnection position, and/or two adjacent active sub-patterns are respectively connected to two different signal lines at the disconnection position.

For example, according to embodiments of the present disclosure, the active pattern includes a semiconductor region and a conductor region, and the disconnection position of the active pattern is located in the conductor region.

For example, according to embodiments of the present disclosure, a material of the semiconductor region includes polysilicon, and a material of the conductor region includes doped polysilicon.

For example, according to embodiments of the present disclosure, each of the plurality of pixel circuits includes transistors, and each of the transistors includes a control electrode, a first electrode, and a second electrode, the semiconductor region is configured to form a channel region of the transistor corresponding to the control electrode, and the conductor region is configured to form the first electrode and the second electrode of the transistor.

For example, according to embodiments of the present disclosure, each of the plurality of pixel circuits includes at least one disconnection position.

For example, according to embodiments of the present disclosure, disconnection positions of the plurality of active patterns corresponding to the plurality of pixel circuits are identical to each other.

For example, according to embodiments of the present disclosure, disconnection positions of active patterns corresponding to at least some pixel circuits are different from each other.

For example, according to embodiments of the present disclosure, the display substrate further includes a first connection layer, the first connection layer is provided on a side of the plurality of active patterns facing away from the base substrate, the first connection layer includes a plurality of connection portions, and at least one of the plurality of connection portions is configured to connect the transistors.

For example, according to embodiments of the present disclosure, the conductor region includes a first conductor portion, and the first conductor portion is disconnected and includes a first disconnection end and a second disconnection end at the disconnection position, the transistors include a first reset transistor and a threshold compensation transistor, the first disconnection end is served as a second electrode of the first reset transistor, and the second disconnection end is served as a second electrode of the threshold compensation transistor, and the plurality of connection portions include a first connection portion, and the first connection portion is configured to connect the first disconnection end of the first conductor portion and the second disconnection end of the first conductor portion.

For example, according to embodiments of the present disclosure, the transistors further include a driving transistor, and the first connection portion is connected to a control electrode of the driving transistor.

For example, according to embodiments of the present disclosure, the conductor region further includes a second conductor portion, and the second conductor portion is disconnected and includes a third disconnection end and a fourth disconnection end at the disconnection position, the transistors further include a first light-emitting control transistor and a second reset transistor, the third disconnection end is served as a second electrode of the first light-emitting control transistor, and the fourth disconnection end is served as a second electrode of the second reset transistor, and the second connection layer includes a second connection portion, and the second connection portion is configured to connect the third disconnection end of the second conductor portion and the fourth disconnection end of the second conductor portion.

For example, according to embodiments of the present disclosure, the display substrate further includes a light-emitting element, the second connection portion is connected to the light-emitting element, the third disconnection end, and the fourth disconnection end, respectively.

For example, according to embodiments of the present disclosure, the conductor region further includes a third conductor portion, and the third conductor portion is disconnected and includes a fifth disconnection end and a sixth disconnection end at the disconnection position, the transistors further include a first reset transistor and a second reset transistor, the fifth disconnection end is served as a first electrode of the first reset transistor, and the sixth disconnection end is served as a first electrode of the second reset transistor, the display substrate further includes a first conductive layer and a second conductive layer, and the plurality of active patterns, the first conductive layer, and the second conductive layer are provided sequentially along a direction away from the base substrate, and the plurality of connection portions include a fifth connection portion and a sixth connection portion, and the second conductive layer includes a first initialization signal line and a second initialization signal line, the first electrode of the first reset transistor is connected to the first initialization signal line through the fifth connection portion, and the first electrode of the second reset transistor is connected to the second initialization signal line through the sixth connection portion.

For example, according to embodiments of the present disclosure, the plurality of pixel circuits are arranged on the base substrate in an array, at least one of the plurality of active patterns includes adjacent disconnection positions spaced apart by at least one row of the pixel circuits.

For example, according to embodiments of the present disclosure, the amounts of the pixel circuits in at least two columns are not equal.

For example, according to embodiments of the present disclosure, active patterns corresponding to at least one column of the pixel circuits are all provided with at least one disconnection position, and/or active patterns corresponding to at least one row of the pixel circuits are all provided with at least one disconnection position.

For example, according to embodiments of the present disclosure, the active patterns corresponding to at least one column of the pixel circuits are all provided with at least one same disconnection position, and/or the active patterns corresponding to at least one row of the pixel circuits are all provided with at least one same disconnection position.

For example, according to embodiments of the present disclosure, the transistors include a threshold compensation transistor, and the threshold compensation transistor is a single-gate transistor.

For example, according to embodiments of the present disclosure, the display substrate further includes a first conductive layer and a second conductive layer, the first conductive layer is located between the plurality of active patterns and the first connection layer, and a control electrode of the threshold compensation transistor is located is connected to a gate line, the second conductive layer is located between the first conductive layer and the first connection layer, the second conductive layer includes a first power supply signal line, and the first power supply signal line extends along the second direction, and the transistors further include a driving transistor, and in the first direction, the first supply power signal line is located on a side of the control electrode of the threshold compensation transistor away from the driving transistor.

For example, according to embodiments of the present disclosure, the conductor region includes a first conductor portion, the transistors further include a first reset transistor, and the first conductor portion is served as a second electrode of the first reset transistor and a second electrode of the threshold compensation transistor, the first connection layer includes a first connection portion, and a control electrode of the driving transistor is connected to the first conductor portion through the first connection portion at a first via hole, and the first power supply signal line includes a main body portion and at least one isolation portion, the main body portion extends along the second direction, the at least one isolation portion is connected to the main body portion and extends along the first direction, and the first via hole is located in a surrounded region formed by the at least one isolation portion and the main body portion.

For example, according to embodiments of the present disclosure, the first power supply signal line further includes at least one shielding portion, the at least one shielding portion is connected to the main body portion and extends along the first direction, and the at least one shielding portion is provided on a side of the main body portion away from the isolation portion, and an orthographic projection of the at least one shielding portion on the base substrate at least partially overlaps with an orthographic projection of the first conductor portion on the base substrate.

For example, according to embodiments of the present disclosure, the display substrate further includes a first conductive layer and a second conductive layer, and the first conductive layer, the second conductive layer, and the first connection layer are arranged sequentially along a direction away from the base substrate, the second conductive layer includes a first power supply signal line, the first power supply signal line includes a plurality of power supply portions, and the plurality of power supply portions are arranged along the second direction and spaced apart from each other, the conductor region includes a first conductor portion, the transistors further include a first reset transistor, a threshold compensation transistor, and a driving transistor, and the first conductor portion is served as a second electrode of the first reset transistor and a second electrode of the threshold compensation transistor, and the plurality of connection portions include a first connection portion, a control electrode of the driving transistor is connected to the first conductor portion through the first connection portion at a first via hole, and the first via hole is located between adjacent power supply portions.

For example, according to embodiments of the present disclosure, each of the plurality of power supply portions includes a main body portion and at least one isolation portion, the at least one isolation portion is connected to the main body portion and extends along the first direction, and the first via hole is located between one main body portion and one isolation portion that are adjacent to each other.

For example, according to embodiments of the present disclosure, the display substrate further includes a first conductive layer, a second conductive layer, and a second connection layer, and the first conductive layer, the second conductive layer, and the second connection layer are arranged sequentially along a direction away from the base substrate, the second connection layer is located on a side of the first connection layer away from the base substrate, the second connection layer includes an initialization connection signal line, and the initialization connection signal line extends along the first direction, the second conductive layer includes a first initialization signal line, and the first initialization signal line extends along the second direction, and the transistors include a first reset transistor, a first electrode of the first reset transistor is connected to the first initialization signal line, and the first initialization signal line is connected to the initialization connection signal line.

For example, according to embodiments of the present disclosure, the plurality of connection portions include a first connection portion, the transistors further include a threshold compensation transistor and a driving transistor, and a second electrode of the first reset transistor, a second electrode of the threshold compensation transistor, and a control electrode of the driving transistor are connected to the first connection portion, and an orthographic projection of the initialization connection signal line on the base substrate at least partially overlaps with an orthographic projection of the first connection portion on the base substrate.

For example, according to embodiments of the present disclosure, the first conductive layer includes a first capacitor portion, the first capacitor portion includes a plurality of first capacitor sub-portions, and the plurality of first capacitor sub-portions are spaced apart from each other along the second direction, and the second conductive layer includes a second capacitor portion, the second capacitor portion includes a plurality of capacitor islands, the plurality of capacitor islands are spaced apart from each other, and each of the plurality of first capacitor sub-portions is provided opposite to at least part of one of the plurality of capacitor islands.

Embodiments of the present disclosure provide a display device, including any one of the display substrates as described above.

### BRIEF DESCRIPTION OF THE DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 is a schematic structural diagram of a display substrate provided by an embodiment of the present disclosure.

FIG. 2A is a schematic diagram of a pixel unit of a display substrate provided by an embodiment of the present disclosure.

FIG. 2B is a schematic diagram of a pixel circuit in a display substrate provided by an embodiment of the present disclosure.

FIG. 3 is a schematic diagram of a display substrate with display defects provided by an embodiment of the present disclosure.

FIG. 4 is a schematic diagram of active patterns of a first area of the display substrate in FIG. 3.

FIG. 5A is a layout diagram of a pixel circuit in a display substrate provided by an embodiment of the present disclosure.

FIG. 5B illustrates active patterns corresponding to the pixel circuit of the display substrate in FIG. 5A.

FIG. 6A is a plan view of active patterns of a display substrate provided by an embodiment of the present disclosure.

FIG. 6B is a plan view of stacked layers of active patterns and a first conductive layer of a display substrate provided by an embodiment of the present disclosure.

FIG. 6C is a plan view of stacked layers of active patterns, a first conductive layer, and a second conductive layer of a display substrate provided by an embodiment of the present disclosure.

FIG. 6D is a plan view of stacked layers of active patterns, a first conductive layer, a second conductive layer, and a first connection layer of a display substrate provided by an embodiment of the present disclosure.

FIG. 6E is a plan view of stacked layers of active patterns, a first conductive layer, a second conductive layer, a first connection layer, and a second connection layer of a display substrate provided by an embodiment of the present disclosure.

FIG. 7A is a plan view of active patterns of a display substrate provided by an embodiment of the present disclosure.

FIG. 7B is a layout diagram corresponds to the pixel circuit in the display substrate provided in FIG. 7A.

FIG. 8A is a plan view of active patterns of a display substrate provided by an embodiment of the present disclosure.

FIG. 8B is a plan view of stacked layers of active patterns and a first conductive layer of a display substrate provided by an embodiment of the present disclosure.

FIG. 8C is a plan view of stacked layers of active patterns, a first conductive layer, and a second conductive layer of a display substrate provided by an embodiment of the present disclosure.

FIG. 8D is a plan view of stacked layers of active patterns, a first conductive layer, a second conductive layer, and a first connection layer of a display substrate provided by an embodiment of the present disclosure.

FIG. 8E is a plan view of stacked layers of active patterns, a first conductive layer, a second conductive layer, a first connection layer, and a second connection layer of a display substrate provided by an embodiment of the present disclosure.

FIG. 9 is a schematic diagram of active patterns of a display substrate provided by an embodiment of the present disclosure.

FIG. 10A is a plan view of active patterns of a display substrate provided by an embodiment of the present disclosure.

FIG. 10B is a schematic diagram of a first conductive layer of a display substrate provided by an embodiment of the present disclosure.

FIG. 10C is a schematic diagram of a second conductive layer of a display substrate provided by an embodiment of the present disclosure.

FIG. 10D is a schematic diagram of a first connection layer of a display substrate provided by an embodiment of the present disclosure.

FIG. 10E is a schematic diagram of a second connection layer of a display substrate provided by an embodiment of the present disclosure.

FIG. 10F is a plan view of stacked layers of active patterns and a first conductive layer of a display substrate provided by an embodiment of the present disclosure.

FIG. 10G is a plan view of stacked layers of active patterns, a first conductive layer, and a second conductive layer of a display substrate provided by an embodiment of the present disclosure.

FIG. 10H is a plan view of stacked layers of active patterns, a first conductive layer, a second conductive layer, and a first connection layer of a display substrate provided by an embodiment of the present disclosure.

FIG. 10I is a plan view of stacked layers of active patterns, a first conductive layer, a second conductive layer, a first connection layer, and a second connection layer of a display substrate provided by an embodiment of the present disclosure.

FIG. 11A is a plan view of active patterns of a display substrate provided by an embodiment of the present disclosure.

FIG. 11B is a plan view of stacked layers of active patterns and a first conductive layer of a display substrate provided by an embodiment of the present disclosure.

FIG. 11C is a plan view of stacked layers of active patterns, a first conductive layer, and a second conductive layer of a display substrate provided by an embodiment of the present disclosure.

FIG. 11D is a plan view of stacked layers of active patterns, a first conductive layer, a second conductive layer, and a first connection layer of a display substrate provided by an embodiment of the present disclosure.

FIG. 11E is a plan view of stacked layers of active patterns, a first conductive layer, a second conductive layer, a first connection layer, and a second connection layer of a display substrate provided by an embodiment of the present disclosure.

FIG. 12A is a plan view of active patterns of a display substrate provided by an embodiment of the present disclosure.

FIG. 12B is a schematic diagram of a first conductive layer of a display substrate provided by an embodiment of the present disclosure.

FIG. 12C is a schematic diagram of a second conductive layer of a display substrate provided by an embodiment of the present disclosure.

FIG. 12D is a schematic diagram of a first connection layer of a display substrate provided by an embodiment of the present disclosure.

FIG. 12E is a schematic diagram of a second connection layer of a display substrate provided by an embodiment of the present disclosure.

FIG. 12F is a plan view of stacked layers of active patterns and a first conductive layer of a display substrate provided by an embodiment of the present disclosure.

FIG. 12G is a plan view of stacked layers of active patterns, a first conductive layer, and a second conductive layer of a display substrate provided by an embodiment of the present disclosure.

FIG. 12H is a plan view of stacked layers of active patterns, a first conductive layer, a second conductive layer, and a first connection layer of a display substrate provided by an embodiment of the present disclosure.

FIG. 12I is a plan view of stacked layers of active patterns, a first conductive layer, a second conductive layer, a first connection layer, and a second connection layer of a display substrate provided by an embodiment of the present disclosure.

FIG. 13 is a schematic diagram of a hollowed-out region included in a display substrate provided by an embodiment of the present disclosure.

### DETAILED DESCRIPTION

In order to make objectives, technical solutions and advantages of the embodiments of the present disclosure more clear, the technical solutions of the embodiments will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present invention belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects.

Features such as “vertical” and “same” used in the embodiments of the present disclosure include features such as “vertical” and “same” in the strict sense, as well as “approximately vertical” and “approximately same” and other situations that contain certain errors. Considering the measurement and errors associated with a specific amount of measurement (that is, the restriction of the measurement system), the measurement is represented within an acceptable deviation range for specific values determined by those skilled in the art. The “center” in the embodiments of the present disclosure may include a position strictly located at the geometric center and a position of an approximate center in a small region around the geometric center. For example, “approximately” may mean within one or more standard deviations, or within 10% or 5% of the numerical value.

With the development of display technology, the existing designs of notch screens or water drop screens are gradually unable to meet the needs of users for high screen-to-body ratio of the display substrate, and a series of display substrates with light-transmitting display regions have emerged as the times require. In this type of display substrate, hardware such as a photosensitive sensor (such as a camera) can be placed in the light-transmitting display region. Because there is no need to punch holes, it is possible to make a true full screen while ensuring the practicability of the display substrate.

In the related art, a display substrate with an under-screen camera generally includes a first display region for normal display and a second display region for placing the camera. The second display region generally includes a plurality of light-emitting elements and a plurality of pixel circuits, each pixel circuit is connected to a light-emitting element, and is configured to drive the light-emitting element to emit light, and the pixel circuit and light-emitting element connected to each other overlap with each other in a direction perpendicular to the display substrate.

FIG. 1 is a schematic structural diagram of a display substrate provided by an embodiment of the present disclosure.

As illustrated in FIG. 1, the display substrate may include a base substrate. The display substrate includes a first display region R1 and a second display region R2, and the first display region R1 is located on at least one side of the second display region R2. For example, in some embodiments, the first display region R1 surrounds the second display region R2. That is, the second display region R2 can be surrounded by the first display region R1. The second display region R2 may also be provided at other positions, and the position of the second display region R2 can be determined according to requirements. For example, the second display region R2 may be located at the middle of the top of the base substrate BS, or may be located at the upper left corner or the upper right corner of the base substrate BS. For example, hardware such as a photosensitive sensor (e.g., a camera) is provided in the second display region R2 of the display substrate. For example, the second display region R2 is a light-transmitting display region, and the first display region R1 is a display region. For example, the first display region R1 is opaque and only used for display.

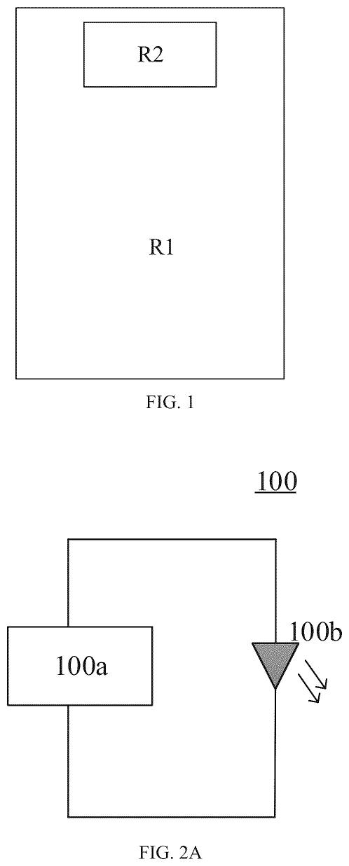

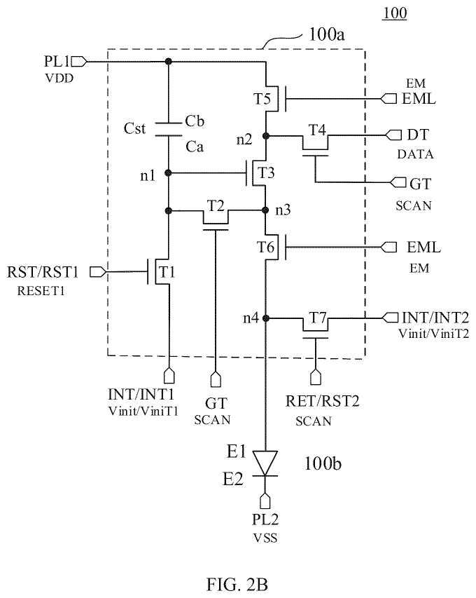

FIG. 2A is a schematic diagram of a pixel unit of a display substrate provided by an embodiment of the present disclosure. The display substrate includes a pixel unit 100, and the pixel unit 100 is located on the base substrate. For example, each pixel unit corresponds to one sub-pixel. As illustrated in FIG. 2A, the pixel unit 100 includes a pixel circuit 100a and a light-emitting element 100b, and the pixel circuit 100a is configured to drive the light-emitting element 100b. For example, the pixel circuit 100a is configured to provide a driving current to drive the light-emitting element 100b to emit light. For example, the light-emitting element 100b is an organic light-emitting diode (OLED), and the light-emitting element 100b emits red light, green light, blue light, or white light under the driving of its corresponding pixel circuit 100b. The color of light emitted by the light-emitting element 100b can be determined according to requirements.

For example, in order to improve the light transmittance of the second display region R2, only light-emitting elements are provided in the second display region R2, and pixel circuits for driving the light-emitting elements in the second display region R2 are provided in the first display region R1. That is, the light transmittance of the second display region R2 is improved by separately providing the light-emitting element and the pixel circuit. For example, the pixel circuit 100a is a low temperature polysilicon (LTPS) AMOLED pixel circuit that is common in the related art.

FIG. 2B is a schematic diagram of a pixel circuit in a display substrate provided by an embodiment of the present disclosure.

As illustrated in FIG. 2B, the pixel unit 100 includes a pixel circuit 100a and a light-emitting element 100b. The pixel circuit 100a includes six switching transistors (T1-T2, T4-T7), one driving transistor T3, and one storage capacitor Cst. The six switching transistors are a first reset transistor T1, a threshold compensation transistor T2, a data writing transistor T4, a first light-emitting control transistor T6, a second light-emitting control transistor T5, and a second reset transistor T7, respectively. The light-emitting element 100b includes a first electrode E1, a second electrode E2, and a light-emitting functional layer located between the first electrode E1 and the second electrode E2. For example, the first electrode E1 is an anode, and the second electrode E2 is a cathode. For example, the first reset transistor T1 and the threshold compensation transistor T2 may each adopt a dual-gate thin film transistor (TFT) to reduce leakage.

As illustrated in FIG. 2B, the display substrate includes a control line GT, a data line DT, a first power supply line PL1, a second power supply line PL2, a light-emitting control signal line EML, an initialization signal line INT, a reset control signal line RST and the like. For example, the reset control signal line RST includes a first reset control signal line RST1 and a second reset control signal line RST2. The first power supply line PL1 is configured to provide a constant first voltage signal VDD to the pixel unit 100, the second power supply line PL2 is configured to provide a constant second voltage signal VSS to the pixel unit 100, and the first voltage signal VDD is greater than the second voltage signal VSS. The control line GT is configured to provide a scanning signal SCAN to the pixel unit 100, the data line DT is configured to provide a data signal DATA (for example, a data voltage VDATA) to the pixel unit 100, the light-emitting control signal line EML is configured to provide a light-emitting control signal EM to the pixel unit 100, the first reset control signal line RST1 is configured to provide a first reset control signal RESET1 to the pixel unit 100, and the second reset control signal line RST2 is configured to provide the scanning signal SCAN to the pixel unit 100. The first initialization signal line INT1 is configured to provide a first initialization signal ViniT1 to the pixel unit 100. The second initialization signal line INT2 is configured to provide a second initialization signal ViniT2 to the pixel unit 100. For example, the first initialization signal ViniT1 and the second initialization signal ViniT2 are constant voltage signals, the magnitude of which may be, for example, between the first voltage signal VDD and the second voltage signal VSS, but not limited thereto. For example, the first initialization signal ViniT1 and the second initialization signal ViniT2 are both less than or equal to the second voltage signal VSS. For example, in some embodiments, the first initialization signal line INT1 is connected to the second initialization signal line INT2, and the first initialization signal line INT1 and the second initialization signal line INT2 are both configured to provide an initialization signal Vinit to the pixel unit 100, that is, the first initialization signal line INT1 and the second initialization signal line INT2 are both called the initialization signal line INT, and the first initialization signal ViniT1 and the second initialization signal ViniT2 are equal, both are Vinit.

As illustrated in FIG. 2B, the driving transistor T3 is electrically connected to the light-emitting element 100b, and outputs a driving current to drive the light-emitting element 100b to emit light, under the control of signals such as the scanning signal SCAN, the data signal DATA, the first voltage signal VDD, the second voltage signal VSS, etc.

For example, the light-emitting element 100b includes an organic light-emitting diode (OLED), and the light-emitting element 100b emits red light, green light, blue light, or white light under the driving of its corresponding pixel circuit 10a. For example, one pixel includes a plurality of pixel units. One pixel may include a plurality of pixel units that emit light of different colors. For example, one pixel includes a pixel unit that emits red light, a pixel unit that emits green light, and a pixel unit that emits blue light, but it is not limited thereto. The amount of pixel units included in one pixel and the light output of each pixel unit can be determined according to requirements.

For example, as illustrated in FIG. 2B, a control electrode of the data writing transistor T4 is connected to the control line GT, a first electrode of the data writing transistor T4 is connected to the data line DT, and a second electrode of the data writing transistor T4 is connected to a first electrode of the driving transistor T3.

For example, as illustrated in FIG. 2B, the pixel circuit 100a further includes a threshold compensation transistor T2, a control electrode of the threshold compensation transistor T2 is connected to the control line GT, a first electrode of the threshold compensation transistor T2 is connected to a second electrode of the driving transistor T3, and a second electrode of the threshold compensation transistor T2 is connected to a control electrode of the driving transistor T3.

For example, as illustrated in FIG. 2B, the display substrate further includes a light-emitting control signal line EML, the pixel circuit 100a further includes a first light-emitting control transistor T6 and a second light-emitting control transistor T5, a control electrode of the second light-emitting control transistor T5 is connected to the light-emitting control signal line EML, a first electrode of the second light-emitting control transistor T5 is connected to the first power supply line PL1, and a second electrode of the second light-emitting control transistor T5 is connected to the first electrode of the driving transistor T3. A control electrode of the first light-emitting control transistor T6 is connected to the light-emitting control signal line EML, a first electrode of the first light-emitting control transistor T6 is connected to the second electrode of the driving transistor T3, and a second electrode of the first light-emitting control transistor T6 is connected to a first electrode of the light-emitting element 100b.

As illustrated in FIG. 2B, a second electrode of the first reset transistor T1 is connected to the control electrode of the driving transistor T3, and is configured to reset the control electrode of the driving transistor T3, and the second reset transistor T7 is connected to the first electrode E1 of the light-emitting element 100b, and is configured to reset the first electrode E1 of the light-emitting element 100b. The first initialization signal line INT1 is connected to the control electrode of the driving transistor T3 through the first reset transistor T1. The second initialization signal line INT2 is connected to the first electrode E1 of the light-emitting element 100b through the second reset transistor T7. For example, the first initialization signal line INT1 and the second initialization signal line INT2 are connected to be input with the same initialization signal, but are not limited thereto. In some embodiments, the first initialization signal line INT1 and the second initialization signal line INT2 may be insulated from each other and configured to input signals, respectively.

For example, as illustrated in FIG. 2B, a first electrode of the first reset transistor T1 is connected to the first initialization signal line INT1, the second electrode of the first reset transistor T1 is connected to the control electrode of the driving transistor T3, a first electrode of the second reset transistor T7 is connected to the second initialization signal line INT2, and a second electrode of the second reset transistor T7 is connected to the first electrode E1 of the light-emitting element 100b. For example, as illustrated in FIG. 2B, a control electrode of the first reset transistor T1 is connected to the first reset control signal line RST1, and a control electrode of the second reset transistor T7 is connected to the second reset control signal line RST2.

As illustrated in FIG. 2B, the first power supply line PL1 is configured to provide the first voltage signal VDD to the pixel circuit 100a. The pixel circuit further includes a storage capacitor Cst, a first electrode Ca of the storage capacitor Cst is connected to the control electrode of the driving transistor T3, and a second electrode Cb of the storage capacitor Cst is connected to the first power supply line PL1.

For example, FIG. 2B further illustrates a first node n1, a second node n2, a third node n3, and a fourth node n4. The second electrode of the first reset transistor T1, the second electrode of the threshold compensation transistor T2, the control electrode of the driving transistor T3, and the first electrode of the storage capacitor Cst are connected to each other at the first node n1, the first electrode of the driving transistor T3, the second electrode of the data writing transistor T4, and the second electrode of the second light-emitting control transistor T5 are connected to each other at the second node n2; the first electrode of the threshold compensation transistor T2, the second electrode of the driving transistor T3, and the first electrode of the first light-emitting control transistor T6 are connected to each other at the third node n3; and the second electrode of the first light-emitting control transistor T6, the second electrode of the second reset transistor T7, and the first electrode of the light-emitting element are connected to each other at the fourth node.

For example, as illustrated in FIG. 2B, the display substrate further includes the second power supply line PL2, and the second power supply line PL2 is connected to the second electrode E2 of the light-emitting element 100b.

Based on the above-mentioned research results, however, the inventor(s) of the present disclosure found that due to the continuous introduction of under-screen display technology, the pixel layout environment of the entire display substrate would be changed due to the arrangement of the second display region R2 (refer to FIG. 1) on the display substrate, which would lead to a problem of display defects. For example, in some practices, vertical Mura and other possible display defects may appear on the display substrate, thereby affecting the display effect.

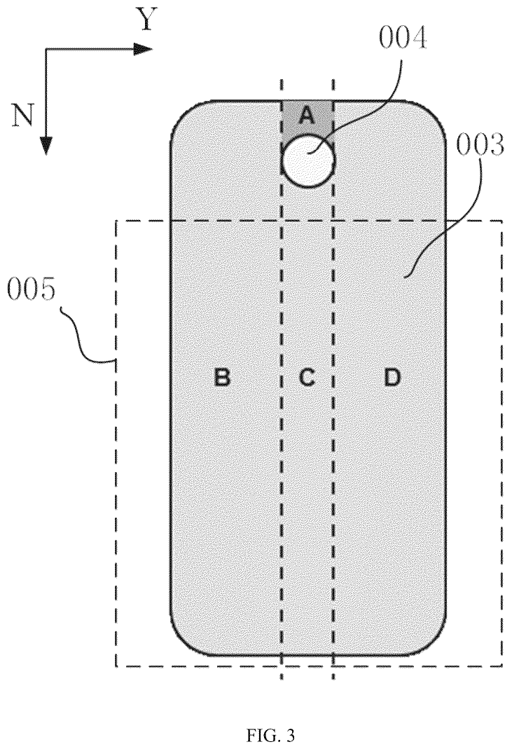

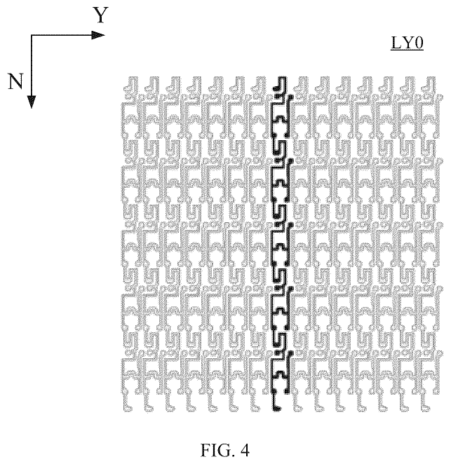

FIG. 3 is a schematic diagram of a display substrate with display defects provided by an embodiment of the present disclosure. FIG. 4 is a schematic diagram of active patterns of a main display region of the display substrate in FIG. 3.

Referring to FIG. 1, FIG. 3 and FIG. 4, a first area 003 in the display substrate corresponds to the first display region R1, a second area 004 corresponds to the second display region R2, the first area 003 includes a first region A, a second region B, a third region C, and a fourth region D, the first region A and the third region C are located on opposite sides of the second region 004, respectively, and the area of the first region A is smaller than the area of the third region C. The second region B and the fourth region D are symmetrically arranged relative to the third region C. For example, in some embodiments of the present disclosure, the structure corresponding to the second area 004 of the display substrate may be partially removed to facilitate placement of sensors, for example, the sensors may include a camera and the like.

FIG. 4 is active patterns corresponding to the first area 003 of the display substrate in FIG. 3. According to FIG. 4, it can be seen that the active patterns in the same column in the display substrate are a structure connected together. Therefore, in the process of ESD (Electro-Static discharge) of the display substrate, the ESD environment of the active patterns in the first region A is significantly different from that in the second region B or the fourth region D, while the ESD environment of the active patterns in the third region C is slightly different. Therefore, as illustrated in FIG. 3, the display effect of the first region A is significantly different from that of the second region B, the third region C, and the fourth region D, which may form a very obvious Mura and other possible display defects.

The embodiments of the present disclosure provide a display substrate and a display device. The display substrate includes a base substrate and a plurality of pixel circuits, and the plurality of pixel circuits are arranged on the base substrate in an array. The plurality of pixel circuits include a plurality of active patterns, each of the plurality of active patterns extends along a first direction, the plurality of active patterns are arranged along a second direction, adjacent active patterns are spaced apart from each other in the second direction, and at least one of the plurality of active patterns includes at least one disconnection position to form a plurality of active sub-patterns independent of each other.

The embodiments of the present disclosure enable the ESD environment of the active patterns in each region of the display substrate uniform by breaking the active patterns in the pixel circuit into a plurality of independent active sub-patterns, which can effectively reduce the impact caused by the structural differences of the active patterns in the process such as ESD, etc., improve the display effect of the display substrate, and improve the yield of the product.

The display substrate and the display device provided by the embodiments of the present disclosure will be described below with reference to the drawings. The display substrate in the embodiments of the present disclosure is based on the principle of the pixel circuit illustrated in FIG. 2B.

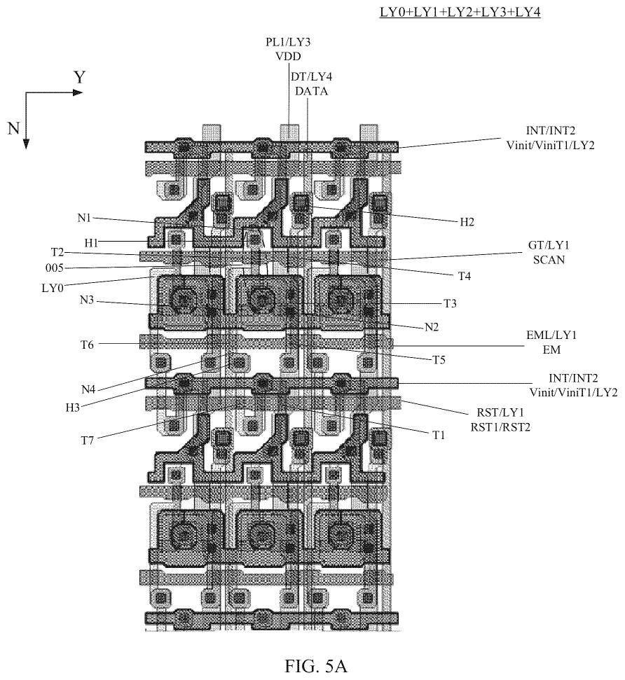

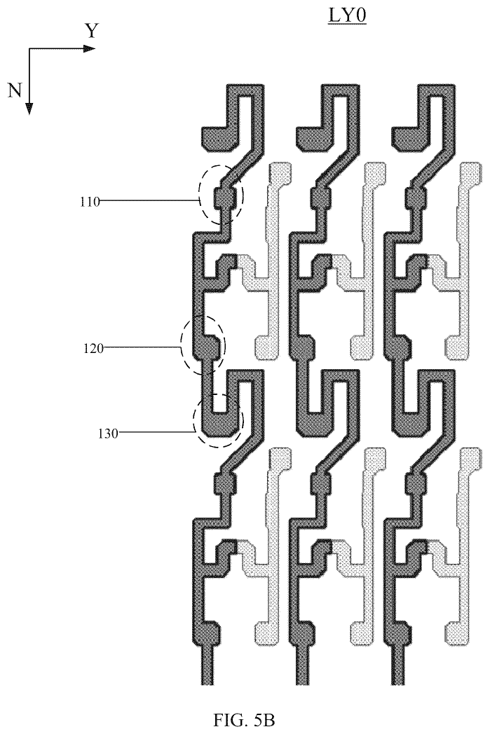

FIG. 5A is a layout diagram of a pixel circuit in a display substrate provided by an embodiment of the present disclosure. FIG. 5B illustrates active patterns corresponding to the pixel circuit of the display substrate in FIG. 5A.

For example, in order not to affect the basic patterning of the display substrate as much as possible, and to take into account manufacturing and cost control factors, the embodiments of the present disclosure provide the disconnection position of the active pattern in a region that may have a small impact on the pixel circuit, for example, at a via hole and other positions.

Referring to FIG. 5A and FIG. 5B, the display substrate includes an active pattern layer LY0, a first conductive layer LY1, a second conductive layer LY2, a first connection layer LY3, and a second connection layer LY4 sequentially arranged on the base substrate, and an insulating layer is arranged between two adjacent above-mentioned layers. For example, the first connection layer LY3 is connected to the second electrode of the first reset transistor T1 through a via hole H1, and the second connection layer LY4 is connected to the first connection layer LY3 through a via hole H2.

As illustrated in FIG. 5A, the display substrate includes a first conductor portion N1, a second conductor portion N2, a third conductor portion N3, and a fourth conductor portion N4. The first conductor portion N1 is served as the second electrode of the first reset transistor T1 and the second electrode of the threshold compensation transistor T2 which are integrally formed with the first conductor portion N1 in the active pattern layer LY0, and the control electrode of the driving transistor T3 is connected to the first conductor portion N1 at the first via hole H1 through a connection portion 005 in the first connection layer LY3. The first electrode of the driving transistor T3 and the second conductor portion N2 are served as the second electrode of the data writing transistor T4 and the second electrode of the first light-emitting control transistor T5, and the second conductor portion N2 is integrally formed with the active pattern layer LY0. The first electrode of the threshold compensation transistor T2 is connected to the third conductor portion N3, and the third conductor portion N3 is served as the second electrode of the driving transistor T3 and the first electrode of the second light-emitting control transistor T6 which are integrally formed with the third conductor portion N3 in the active pattern layer LY0. The fourth conductor portion N4 is served as the second electrode of the second light-emitting control transistor T6 and the second electrode of the second reset transistor T7, and is integrally formed with the active pattern layer LY0, and the first electrode E1 of the light-emitting element is connected to the fourth conductor portion N4 through the via hole H3.

Referring to FIG. 5A and FIG. 5B, the selected disconnection position in the embodiment of the present disclosure is a first disconnection position 110, or a second disconnection position 120, or a third disconnection position 130 in the active patterns of the display substrate. The first disconnection position 110 corresponds to the first conductor portion N1 in the pixel circuit of the display substrate, the second disconnection position 120 corresponds to the fourth conductor portion N4 in the pixel circuit of the display substrate, and the third disconnection position 130 corresponds to the connection position of the first electrode of the first reset transistor T1 and the first electrode of the second reset transistor T7 in the pixel circuit of the display substrate. The first conductor portion N1 corresponds to the node n1 in the pixel circuit 100, and the second conductor portion N4 corresponds to the node n4 in the pixel circuit 100. Therefore, selecting the above-mentioned disconnection positions can reduce the design and manufacturing cost of the pixel circuit, and facilitate operation.

Of course, in some embodiments, other positions may be selected as the disconnection positions, and the embodiments of the present disclosure are not limited in this aspect.

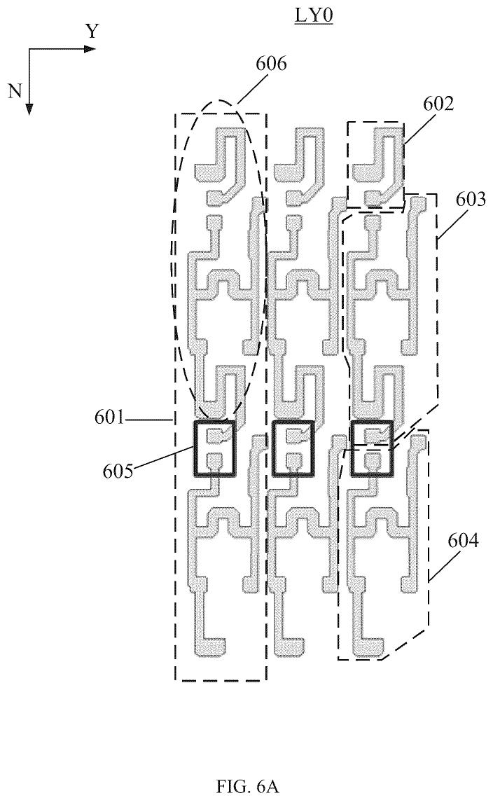

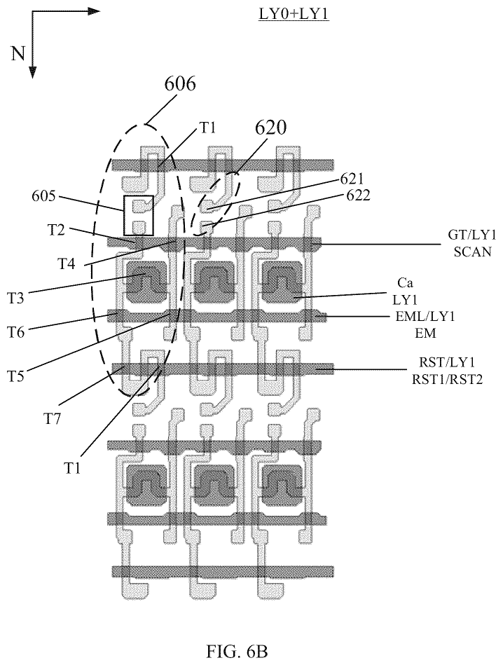

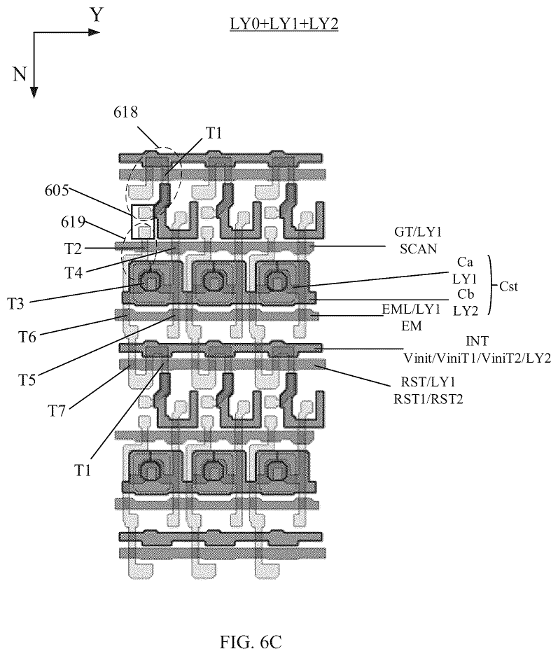

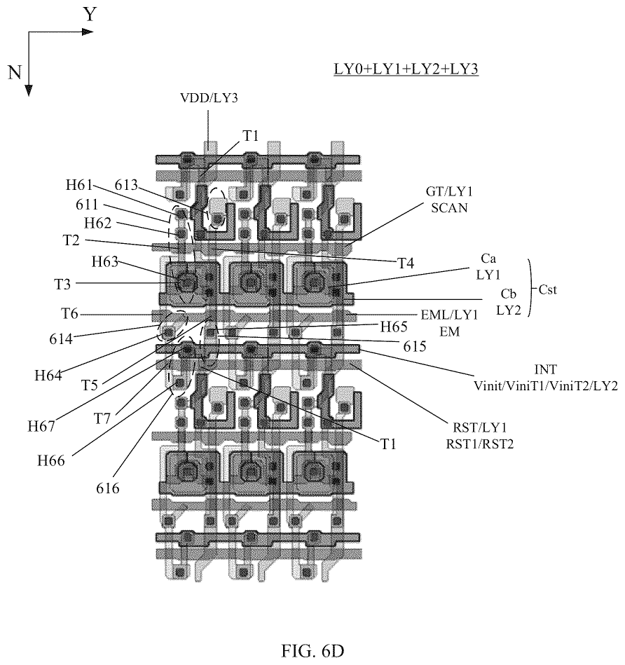

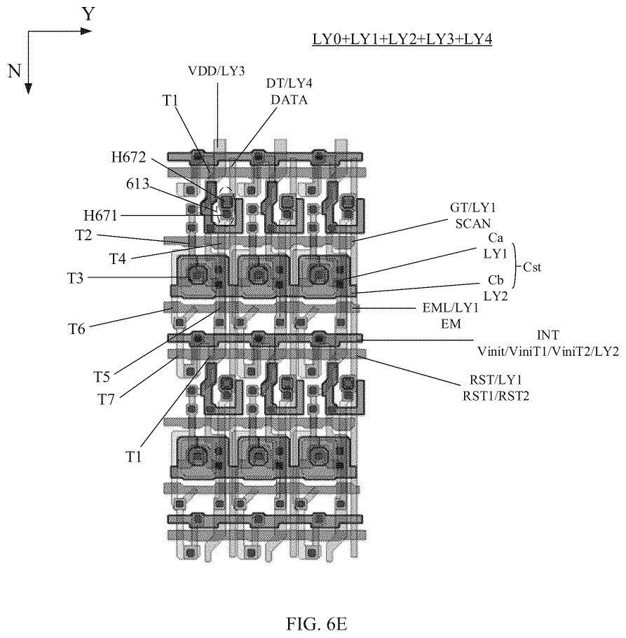

FIG. 6A is a plan view of active patterns of a display substrate provided by an embodiment of the present disclosure.

As illustrated in FIG. 6A, the display substrate includes a base substrate and a plurality of pixel circuits, and the plurality of pixel circuits are arranged on the base substrate in an array. The plurality of pixel circuits include a plurality of active patterns 601, each of the plurality of active patterns 601 extends along a first direction N and are arranged along a second direction Y, adjacent active patterns 601 are spaced apart from each other in the second direction Y, and at least one of the plurality of active patterns 601 includes at least one disconnection position to form a plurality of active sub-patterns independent of each other.

As illustrated in FIG. 6A, the display substrate includes the active pattern layer LY0, and the active pattern layer LY0 includes a plurality of active patterns 601. In the present embodiment, the disconnection position of the active pattern 601 is a first disconnection end 605, of course, in some embodiments, the disconnection position may be other positions in the active pattern 601. Tus, the disconnected active patterns 601 form a plurality of active sub-patterns 602, a plurality of active sub-patterns 603, and a plurality of active sub-patterns 604, and the plurality of active sub-patterns 602, the plurality of active sub-pattern 603, and the plurality of active sub-patterns 604 are independent of each other. As illustrated in FIG. 6A, each active pattern 601 includes an active sub-pattern 602, an active sub-pattern 603, and an active sub-pattern 604. For example, in the active pattern 601, each pixel circuit includes an active unit 606 to drive the light-emitting element to emit red light, green light, blue light, white light, or the like.

Referring to FIG. 3 and FIG. 6A, by breaking the continuous active pattern 601 into a plurality of active sub-patterns, isolating the active pattern 601, separating the plurality of active sub-patterns from each other, and providing the plurality of active sub-patterns independently, the ESD environment of the active patterns in each region of the display substrate can be uniform, thus reducing the difference of the ESD impact in the process. For example, compared with the second region B or the fourth region D, the ESD environment difference of the active pattern in the first region A and the active pattern in the third region C is also smaller. Therefore, the display effect of the first region A will not be significantly different from that of the second region B, the third region C, and the fourth region D, which can reduce the Mura and other possible display defects caused by the ESD environment differences of the active patterns.

For example, as illustrated in FIG. 6A, the active pattern 601 may include a semiconductor region and a conductor region, and the disconnection position of the active pattern 601 is located in the conductor region.

FIG. 6B is a plan view of stacked layers of active patterns and a first conductive layer of a display substrate provided by an embodiment of the present disclosure.

As illustrated in FIG. 6B, the orthographic projection of the first conductive layer LY1 on the base substrate at least partially overlaps with the orthographic projection of the active pattern layer LY0 on the base substrate.

For example, in the manufacturing process of the display substrate, a self-alignment process is used to perform a converting-into-conductor process on the active pattern layer LY0 with the first conductive layer LY1 as a mask. The active pattern layer LY0 may be formed by patterning a semiconductor thin film. A region, subjected to the converting-into-conductor process, of the active pattern layer LY0 is a conductor region, while a region, not subjected to the converting-into-conductor process, of the active pattern layer LY0 is a semiconductor region. Because the conductor region in the active pattern layer LY0 is not covered by the first conductive layer LY1, providing the disconnection position in the conductor region cannot damage the basic patterning of the display substrate, reduce the possible impact on the pixel circuit, facilitate operation, and reduce manufacturing cost.

For example, the pixel circuit in the display substrate includes a transistor, and the transistor includes a control electrode, a first electrode, and a second electrode. The semiconductor region is configured to form a channel region of the transistor corresponding to the control electrode, and the conductor region is configured to form the first electrode and the second electrode of the transistor.

For example, the active pattern layer LY0 can be doped by ion implantation, so that the portion of the active pattern layer LY0 that is not covered by the first conductive layer LY1 is subjected to the converting-into-conductor process to form the first electrode and the second electrode of the threshold compensation transistor T2, the first electrode and the second electrode of the driving transistor T3, the first electrode and the second electrode of the data writing transistor T4, the first electrode and the second electrode of the first light-emitting control transistor T6, the first electrode and the second electrode of the second light-emitting control transistor T5, the first electrode and the second electrode of the first reset transistor T1, and the first electrode and the second electrode of the second reset transistor T7. The portion of the active pattern layer LY0 covered by the first conductive layer LY1 is the semiconductor region, and retains semiconductor characteristics, forming a channel region of the threshold compensation transistor T2, a channel region of the driving transistor T3, a channel region of the data writing transistor T4, a channel region of the first light-emitting control transistor T6, a channel region of the second light-emitting control transistor T5, a channel region of the first reset transistor T1, and a channel region of the second reset transistor T7.

For example, as illustrated in FIG. 6B, the second electrode of the second reset transistor T7 and the second electrode of the first light-emitting control transistor T6 are integrally formed; the first electrode of the driving transistor T3, the second electrode of the data writing transistor T4, and the second electrode of the second light-emitting control transistor T5 are integrally formed. The first electrode of the second reset transistor T7 and the first electrode of the first reset transistor T1 may be integrally formed. Thus, the positions of the respective transistors in the pixel circuit are arranged in the conductor region and the semiconductor region in the active pattern layer LY0.

For example, the material of the semiconductor region in the display substrate includes polysilicon, and the material of the conductor region includes doped polysilicon.

For example, the channel regions of the transistors used in the embodiments of the present disclosure may be made of monocrystalline silicon, polysilicon (such as low temperature polysilicon) or metal oxide semiconductor material (such as IGZO. AZO, etc.). In an embodiment, the transistors are all P-type low temperature polysilicon (LTPS) thin film transistors. In another embodiment, the threshold compensation transistor T2 and the first reset transistor T1 directly connected to the control electrode of the driving transistor T3 are metal oxide semiconductor thin film transistors, that is, the materials of the channel regions of the transistors are metal oxide semiconductor materials (such as IGZO, AZO, etc.), and the metal oxide semiconductor thin film transistor has a lower leakage current, which can help reduce the leakage current of the control electrode of the driving transistor T3.

For example, the transistors used in the embodiments of the present disclosure may include various structures, such as top-gate, bottom-gate, or dual-gate structures. In an embodiment, the threshold compensation transistor T2 and the first reset transistor T1 directly connected to the control electrode of the driving transistor T3 are dual-gate thin film transistors, which can help reduce the leakage current of the control electrode of the driving transistor T3.

According to FIG. 6B, the active pattern 601 is disconnected at the first disconnection end 605, and the first disconnection end 605 is located in the conductor region of the active pattern 601. In this case, the second electrode of the first reset transistor T1 is disconnected from the second electrode of the threshold compensation transistor T2.

FIG. 6C is a plan view of stacked layers of active patterns, a first conductive layer, and a second conductive layer of a display substrate provided by an embodiment of the present disclosure.

Referring to FIG. 6B and FIG. 6C, the first conductive layer LY1 provides the pixel circuit with the control line GT, the light-emitting control signal line EML, the reset control signal line RST (including the first reset control signal line RST1 and the second reset control signal line RST2), and the first electrode Ca of the storage capacitor Cst, and the control line GT, the light-emitting control signal line EML, and the reset control signal line RST all extend along the second direction Y. The second conductive layer LY2 provides the initialization signal line INT for the pixel circuit, and a first initialization signal line ViniT1 and a second initialization signal line ViniT2 are connected to be input with the same initialization signal Vinit. In addition, the second electrode Cb of the storage capacitor Cst is arranged in the second conductive layer LY2.

It can be seen from FIG. 6C that the second conductive layer LY2 has no connection relationship with the first disconnection end 605.

FIG. 6D is a plan view of stacked layers of active patterns, a first conductive layer, a second conductive layer, and a first connection layer of a display substrate provided by an embodiment of the present disclosure.

For example, two adjacent active sub-patterns are connected through the same connecting portion at the disconnected position, and/or two adjacent active sub-patterns are connected to two different signal lines at the disconnected position, respectively.

For example, the display substrate further includes a first connection layer LY3, the first connection layer LY3 is provided on a side of the active pattern 601 facing away from the base substrate, the first connection layer LY3 includes a plurality of connection portions, and at least one of the plurality of connection portions is configured to connect the various transistors.

As illustrated in FIG. 6D, the first connection layer LY3 is provided on the side of the active pattern 601 facing away from the base substrate, and the orthographic projection of the first connection layer LY3 on the base substrate at least partially overlaps with the orthographic projection of the first conductive layer LY1 on the base substrate and the orthographic projection of the second conductive layer LY2 on the base substrate, respectively. The first connection layer LY3 provides the pixel circuit with a first voltage signal line VDD and a plurality of connection portions. For example, the plurality of connection portions include a first connection portion 611, a third connection portion 613, a fourth connection portion 614, a light-emitting control connection portion 615, and a reset control connection portion 616, and the plurality of connection portions can connect the transistors in the display substrate.

For example, referring to FIG. 6B, FIG. 6C and FIG. 6D, the conductor region of the active pattern 601 includes a first conductor portion 620, and the first conductor portion 620 is disconnected and includes a first disconnection end 621 and a second disconnection end 622 at the disconnection position. The plurality of transistors include a first reset transistor T1 and a threshold compensation transistor T2, the first disconnection end 621 is served as a second electrode of the first reset transistor T1, and the second disconnection end 622 is served as a second electrode of the threshold compensation transistor T2. The plurality of connection portions include a first connection portion 611, and the first connection portion 611 is configured to connect the first connection end 621 and the second connection end 622 of the first conductor portion 620.

For example, the plurality of transistors further include a driving transistor T3, and the first connection portion 611 is connected to a control electrode of the driving transistor T3.

Referring to FIG. 6C and FIG. 6D, at the first disconnection end 621, the active sub-pattern 618 and the active sub-pattern 619 are two adjacent active sub-patterns, are connected through the same connection portion, that is, are connected through the first connection portion 611. The first connection portion 611 is connected to the second electrode of the first reset transistor T1 through a via hole H61, at the second disconnection end 622, the first connection portion 611 is connected to the second electrode of the threshold compensation transistor T2 through a via hole H62. The first connection portion 611 is further connected to the control electrode of the driving transistor T3 through a via hole H63. Thus, by providing the first connection portion 611, the second electrode of the first reset transistor T1, the second electrode of the threshold compensation transistor T2, and the control electrode of the driving transistor T3 can be connected together, and the disconnection position of the first conductor portion 620 is connected to the control electrode of the driving transistor T3 through the first connection portion 611, which will not damage the connection structures of other transistors in the pixel circuit, which is beneficial to reducing the manufacturing cost.

In addition, as illustrated in FIG. 6D, the second electrode of the first light-emitting control transistor T6 is integrally formed with the second electrode of the second reset transistor T7, and is connected to the first electrode of the light-emitting element at a via hole H64 through the fourth connection portion 614. The first electrode of the second light-emitting control transistor T5 is connected to the first voltage signal line VDD at a via hole H65 through the light-emitting control connection portion 615. The first electrode of the second reset transistor T7 is connected to one end of the reset control connection portion 616 at a via hole H66, and the other end of the reset control connection portion 616 is connected to the second initialization signal line INT2 at a via hole H67, thereby enabling the first electrode of the second reset transistor T7 to be connected to the second initialization signal line INT2.

FIG. 6E is a plan view of stacked layers of active patterns, a first conductive layer, a second conductive layer, a first connection layer, and a second connection layer of a display substrate provided by an embodiment of the present disclosure.

As illustrated in FIG. 6E, the second connection layer LY4 is provided on a side of the first connection layer LY3 facing away from the base substrate, and the orthographic projection of the second connection layer LY4 on the base substrate at least partially overlaps with the orthographic projection of the first conductive layer LY1 on the substrate, the orthographic projection of the second conductive layer LY2 on the base substrate, and the orthographic projection of the first connection layer LY3 on the base substrate, respectively. The second connection layer LY4 provides the data line DT for the pixel circuit.

Referring to FIG. 6E and FIG. 6D, one end of the third connection portion 613 in the first connection layer LY3 is connected to the first electrode of the data writing transistor T4 through a via hole H671, and the other end of the third connection portion 613 is connected to the data line DT through a via hole H672, that is, the third connection portion 613 is served as an intermediate transfer connector to connect the first electrode of the data writing transistor T4 to the data line DT.

Referring to FIG. 6A-FIG. 6E, because the structure of the pixel circuit of the display substrate in the present embodiment is the same as that in FIG. 5A, the connection relationship between respective transistors, the function and implementation mode of each signal line and data line can be referred to the display substrates illustrated in FIG. 5A and FIG. 5B, which will not be described in detail here.

For example, each pixel circuit in the display substrate includes at least one disconnection position.

Referring to FIG. 5B and FIG. 6A, an optional disconnection position of the active pattern layer LY0 may be the first disconnection position 110, the second disconnection position 120, or the third disconnection position 130. For example, in the active pattern 601, the active unit 606 corresponds to a pixel circuit, and each active unit 606 includes at least one disconnection position, so that each active unit 606 can include at least two active sub-patterns, so that the active sub-patterns in each region of the display substrate have substantially the same ESD environment, thereby reducing Mura and other possible display defects caused by the ESD environment differences of the active sub-patterns.

For example, in order to improve the uniformity and avoid the influence of the ESD environment differences, the disconnection positions of the active patterns corresponding to each pixel circuit in the display substrate may be identical to each other.

Referring to FIG. 5B and FIG. 6A, for example, each active unit 606 includes at least one disconnection position, and the disconnection positions are selected at the first disconnection position 110, or selected at the second disconnection position 120, or selected at the third disconnection position 130 in respective active units 606. Selecting the same disconnection position in respective active units 606 can enable each active unit 606 to include the same active sub-patterns, thus reducing the impact of the ESD environment differences that may be caused by the shape differences of the active sub-patterns, which is easy to ensure and achieve the uniformity of the ESD environment of the active sub-patterns, and also reduce the manufacturing and operation costs.

For example, the disconnection positions of the active patterns corresponding to at least some pixel circuits in the display substrate are different from each other.

Referring to FIG. 5B and FIG. 6A, for example, each active unit 606 includes at least one disconnection position, and the disconnection positions in respective active units 606 are different from each other. For example, the disconnection position in each active unit 606 may be at the first disconnection position 110, or at the second disconnection position 120, or at the third disconnection position 130. For example, the selected disconnection position in each active unit 606 can be determined according to the actual patterning of the pixel circuit. For example, in the case where the patterning space in the pixel circuit is limited or the arrangement of connection components is inconvenient, the disconnection positions in active units 606 can also be provided at different positions according to the actual situation, so that the patterning requirements and functional implementation requirements of the pixel circuit can be better satisfied.

For example, the amounts of pixel circuits in at least two columns in the display substrate are not equal.

Referring to FIG. 3 and FIG. 6A, in the display substrate, a plurality of pixel circuits are arranged in an array, and the pixel circuits in the same column may be discontinuously arranged. For example, a certain spacing distance may be reserved between the pixel circuits in the same column. Correspondingly, a certain spacing distance may be provided between adjacent active units 606 in the same column of active patterns 601.

For example, in the first direction N, the spacing distance is 1/20-⅛ of the maximum dimension of the display substrate; for example, in the first direction N, the spacing distance is 1/15- 1/10 of the maximum dimension of the display substrate; for example, in the first direction N, the spacing distance is 1/12- 1/11 of the maximum dimension of the display substrate. For example, in the case where the pixel circuits in the same column are arranged discontinuously, the display substrate may be, for example, a display substrate provided with a hole as illustrated in FIG. 3, for example, the function can be improved by providing a display substrate with a hole, for example, a camera and other devices can be provided in the region where the hole is located.

Thus, by making the amounts of the pixel circuits in at least two columns in the display substrate unequal, it can be adapted to display substrates with more form requirements, for example, it can be adapted to the display substrate with a hole. In addition, by making a column of active pattern in the display substrate include at least one disconnection position to form a plurality of active sub-patterns, the impact of the ESD environment differences that may be caused by the shape differences of the active sub-patterns can be reduced, and it is easy to ensure and achieve the uniformity of the ESD environment of the active sub-patterns.

For example, the active patterns corresponding to at least one column of the pixel circuits in the display substrate are all provided with at least one disconnection position, and/or active patterns corresponding to at least one row of the pixel circuits in the display substrate are all provided with at least one disconnection position.

For example, referring to FIG. 3, FIG. 5B and FIG. 6A, the display substrate may include at least one column of active patterns in which the active units 606 all includes at least one disconnection position, thus each active unit 606 in the same column includes a plurality of active sub-patterns after being disconnected. That is, there is at least one column of pixel circuits in the display panel, and the active pattern corresponding to each pixel circuit in the column includes at least one disconnection position. For example, the display substrate may include a plurality of columns of active patterns in which the active units 606 all includes at least one disconnection position. For example, the display substrate may include a plurality of columns of adjacent active patterns in which the active units 606 all includes at least one disconnection position. For example, as illustrated in FIG. 3, the second region B and/or the fourth region D may be a region where the active units 606 in the plurality of columns of adjacent active patterns all includes at least one disconnection position. For example, as illustrated in FIG. 3, the first region A, the second region B, and the third region C may be regions where the active units 606 in the plurality of columns of adjacent active patterns all includes at least one disconnection position, for example, as illustrated in FIG. 3, the first region A, the second region B and the fourth region D may be regions where the active units 606 in the plurality of columns of adjacent active patterns all includes at least one disconnection position. Therefore, at least the impact of the ESD environment differences that may be caused by the shape differences of the active sub-patterns in certain regions, such as the first region A, the second region B, the third region C, and the fourth region D, can be reduced, and it is easy to ensure and achieve the uniformity of the ESD environment of the active sub-patterns.

For example, referring to FIG. 3, FIG. 5B and FIG. 6A, the display substrate may include at least one row of active units 606 each including a plurality of active sub-patterns after being disconnected. That is, there is at least one row of pixel circuits in the display panel, and the active pattern corresponding to each pixel circuit in the row includes at least one disconnection position. For example, each row of active units 606 in the third region 005 (as illustrated in FIG. 3) may not be provided with disconnection positions, while active units 606 corresponding to pixel circuits in regions other than the third region 005 in the display substrate may be provided with disconnection positions, in this way, at least the impact of the ESD environment differences that may be caused by the shape differences of the active sub-patterns in the third region 005 or regions other than the third region 005 can be reduced, and it is easy to ensure and achieve the uniformity of the ESD environment for the active sub-patterns.

For example, in the display substrate, the active patterns corresponding to at least one column of the pixel circuits are all provided with at least one same disconnection position, and/or the active patterns corresponding to at least one row of the pixel circuits are all provided with at least one same disconnection position.

In combination with the above description about the disconnection scheme, in the case where the active patterns corresponding to at least one column of the pixel circuits are all provided with at least one same disconnection position, and/or the active patterns corresponding to at least one row of the pixel circuits are all provided with at least one same disconnection position, the shape differences of the active sub-patterns in the selected active pattern for disconnection design can be reduced, thereby further reducing the impact of the ESD environment differences that may be caused by the shape differences of the active sub-patterns, and it is easy to ensure and achieve the uniformity of the ESD environment for the active sub-patterns, and the patterning requirements and functional implementation requirements of the pixel circuit can be better satisfied.

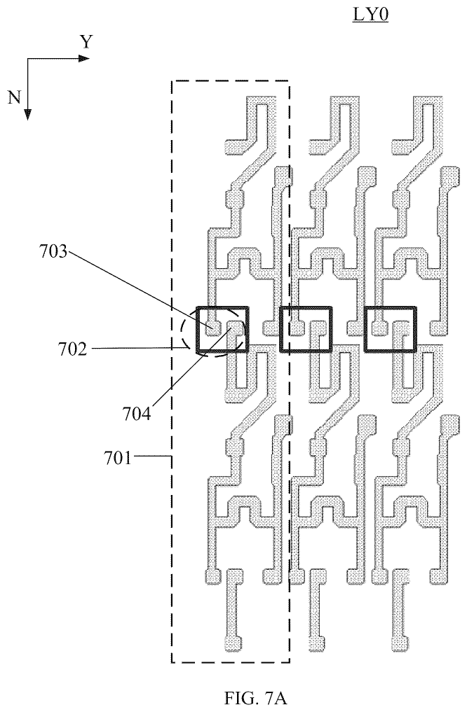

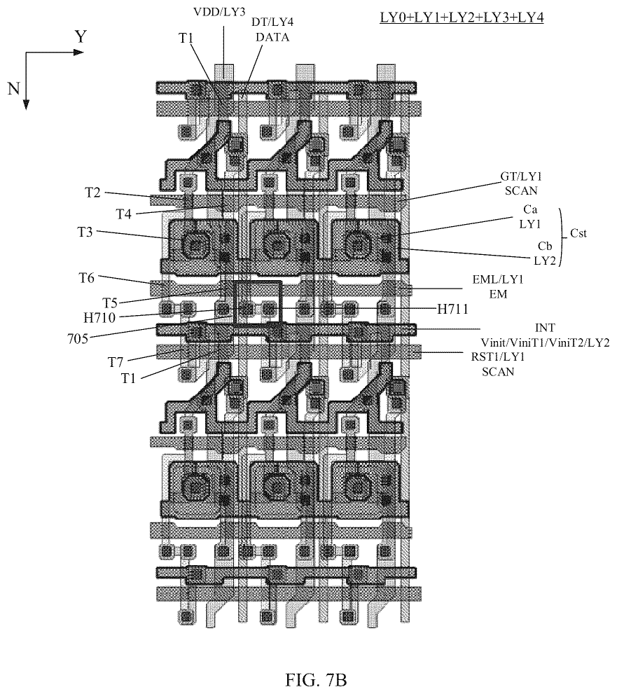

FIG. 7A is a plan view of active patterns of a display substrate provided by an embodiment of the present disclosure. FIG. 7B is a layout diagram corresponding to the pixel circuit in the display substrate provided in FIG. 7A.

Compared with the display substrates provided by the embodiments of FIG. 6A to FIG. 6E, the manufacturing process of the pixel circuits, the stacking relationship between layers, and the connection relationship and function of transistors in the display substrate illustrated in FIG. 7A and FIG. 7B are basically the same as those in FIG. 6A to FIG. 6E, and the difference is that the disconnection positions of the active pattern layer LY0 in FIG. 7A and FIG. 6A are different from that in FIG. 6A to FIG. 6E, so the connection modes at different disconnection positions are different. Referring to FIG. 5B, FIG. 6A and FIG. 7A, the disconnection position of the active pattern layer LY0 in FIG. 6A corresponds to the first disconnection position 110 in FIG. 5B, and the disconnection position of the active pattern layer LY0 in FIG. 7A corresponds to the second disconnection position 120 in FIG. 5B.

For example, referring to FIG. 7A and FIG. 7B, in the active pattern layer LY0 of the display substrate, the conductor region of the active pattern 701 includes a second conductor portion 702, and the second conductor portion 702 is disconnected and includes a third disconnection end 703 and a fourth disconnection end 704 at the disconnection position. The plurality of transistors in the display substrate include the first light-emitting control transistor T6 and the second reset transistor 17, the third disconnection end 703 is served as the second electrode of the first light-emitting control transistor T6, the fourth disconnection end 704 is served as the second electrode of the second reset transistor 17, the second connection layer LY4 includes a second connection portion 705 (as illustrated by the black frame line in FIG. 7B), and the second connection portion 705 is configured to connect the third disconnection end 703 and the fourth disconnection end 704 of the second conductor portion 702.

As illustrated in FIG. 7B, the second connection portion 705 is provided in the first connection layer LY3, the second connection portion 705 is connected to the second electrode of the first light-emitting control transistor T6 through a via hole H710, and the second connection portion 705 is connected to the second electrode of the second reset transistor T7 through a via hole H711.

For example, referring to FIG. 7A and FIG. 7B, the display substrate includes a light-emitting element (not illustrated in the figures), and the second connection portion 705 is connected to the light-emitting element, the third disconnection end 703 and the fourth disconnection end 704, respectively.

For example, referring to FIG. 7A and FIG. 7B, the light-emitting element is provided on a side of the second connection layer LY4 facing away from the base substrate, and the first electrode of the light-emitting element is connected to the second connection portion 705 through the via hole H711 to achieve the connection between the third disconnection end 703 and the fourth disconnection end 704, that is, to achieve the connection between the second electrode of the first light-emitting control transistor T6 and the second electrode of the second reset transistor T7.

By providing the disconnection position of the active pattern layer LY0 in the display substrate at the second disconnection position 120, and connecting respective disconnection ends through the second connection portion 705 in the first connection layer LY3, the normal operation of the pixel circuits in the display substrate can be achieved, while reducing the impact caused by the ESD environment differences of the active pattern 701, thus avoiding the phenomena, caused by the ESD environment differences, such as the Mura and other possible display defects on the display substrate.

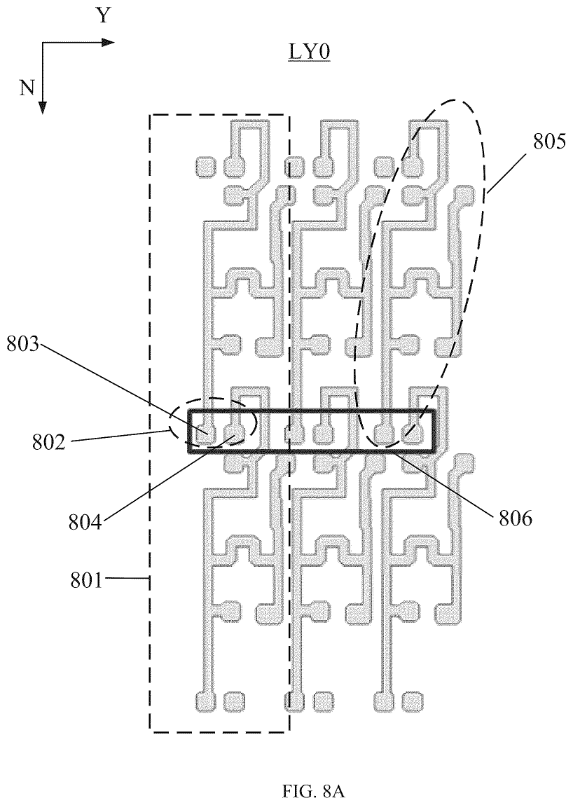

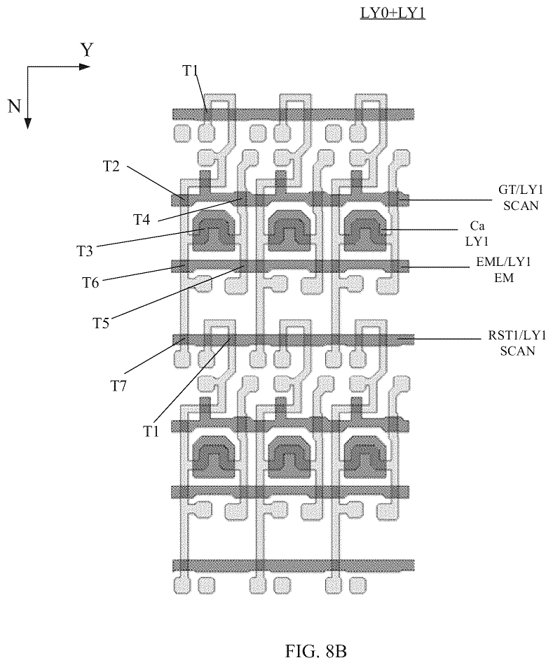

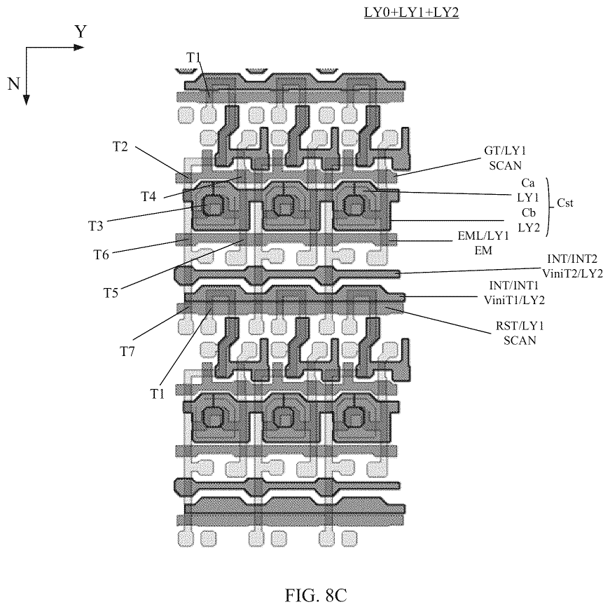

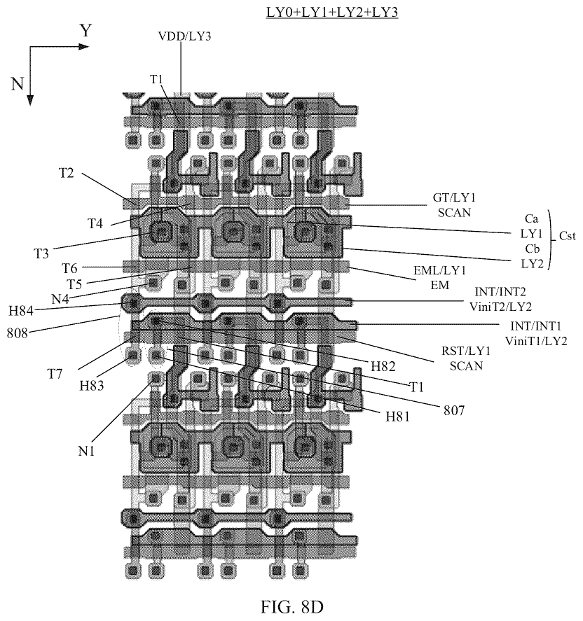

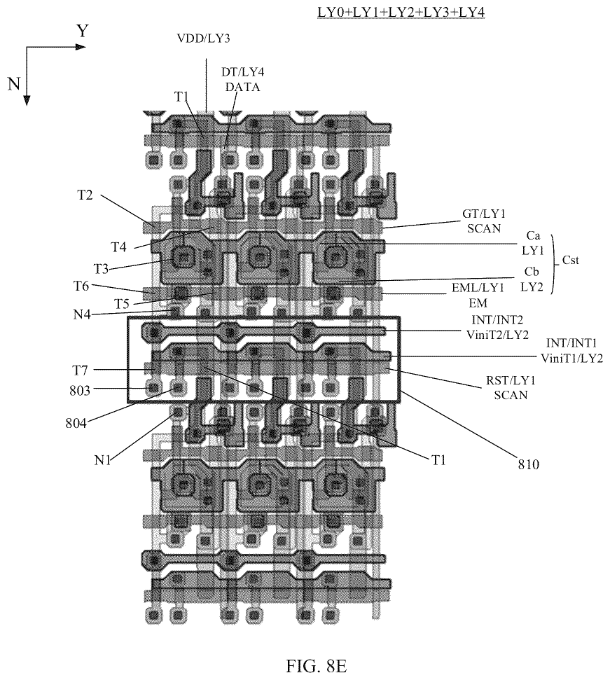

FIG. 8A is a plan view of active patterns of a display substrate provided by an embodiment of the present disclosure. FIG. 8B is a plan view of stacked layers of active patterns and a first conductive layer of a display substrate provided by an embodiment of the present disclosure. FIG. 8C is a plan view of stacked layers of active patterns, a first conductive layer, and a second conductive layer of a display substrate provided by an embodiment of the present disclosure. FIG. 8D is a plan view of stacked layers of active patterns, a first conductive layer, a second conductive layer, and a first connection layer of a display substrate provided by an embodiment of the present disclosure. FIG. 8E is a plan view of stacked layers of active patterns, a first conductive layer, a second conductive layer, a first connection layer, and a second connection layer of a display substrate provided by an embodiment of the present disclosure.

Compared with the display substrates provided by the embodiments of FIG. 6A to FIG. 6E, the manufacturing process of the pixel circuits, the stacking relationship between layers, and the connection relationship and function of transistors in the display substrate illustrated in FIG. 8A-FIG. 8E are basically the same as those of the display substrates provided by the embodiments of FIG. 6A to FIG. 6E, and the difference is that the disconnection positions of the active pattern layer LY0 in FIG. 8A-FIG. 8E are different from that in FIG. 6A to FIG. 6E, so the connection modes at different disconnection positions are different. Referring to FIG. 5B, FIG. 6A, FIG. 7A and FIG. 8A, the disconnection position of the active pattern layer LY0 in FIG. 6A corresponds to the first disconnection position 110 in FIG. 5B, the disconnection position of the active pattern layer LY0 in FIG. 7A corresponds to the second disconnection position 120 in FIG. 5B, and the disconnection position of the active pattern layer LY0 in FIG. 8A corresponds to the third disconnection position 130 in FIG. 5B.

For example, as illustrated in FIG. 8A-FIG. 8C, in the active pattern layer LY0 of the display substrate, the conductor region of the active pattern 801 includes a third conductor portion 802, and the third conductor portion 802 is disconnected and includes a fifth disconnection end 803 and a sixth disconnection end 804; the plurality of transistors in the pixel circuit include a first reset transistor T1 and a second reset transistor T7; the fifth disconnection end 803 is served as a first electrode of the first reset transistor T1, and the sixth disconnection end 804 is served as a first electrode of the second reset transistor 17. The display substrate includes a first conductive layer LY1 and a second conductive layer LY2, and the active pattern layer LY0, the first conductive layer LY1, and the second conductive layer LY2 is arranged sequentially along the direction away from the base substrate, and the plurality of connection portions include a fifth connection portion 807 and a sixth connection portion 808. The second conductive layer LY2 includes a first initialization signal line ViniT1 and a second initialization signal line ViniT2, the first electrode of the first reset transistor T1 is connected to the first initialization signal line ViniT1 through the fifth connection portion 807, and the first electrode of the second reset transistor T2 is connected to the second initialization signal line ViniT2 through the sixth connection portion 808.

For example, referring to FIG. 8A and FIG. 8B, the active pattern 801 includes a plurality of active units 805, and each active unit 805 corresponds to a pixel circuit. The respective active patterns 801 in the display substrate in FIG. 8A each extends along the first direction and are arranged in the second direction Y, and the active units 805 in each row are all disconnected at the corresponding second conductor portions 802, thereby forming a plurality of fifth disconnection ends 803 or a plurality of sixth disconnection ends 804 arranged in the same row. For example, a disconnection region 806 illustrates a plurality of disconnection ends of the plurality of active units 805 arranged in the same row in the second direction Y.

Referring to FIG. 8A and FIG. 8B, after the active pattern 801 is disconnected at the third conductor portion 802, the second electrode of the second reset transistor T7 and the second electrode of the first light-emitting control transistor T6 are connected and formed integrally; the first electrode of the second reset transistor T7 is disconnected from the first electrode of the first reset transistor T1; and the first electrode of the first reset transistor T1 and the second electrode of the threshold compensation transistor T2 are connected and formed integrally. Both the first reset transistor T1 and the threshold compensation transistor T2 are provided in the form of double gates, which is beneficial to reducing leakage.

As illustrated in FIG. 8C, the second conductive layer LY2 provides two initialization signal lines INT for the pixel circuit, that is, a first initialization signal line INT1 and a second initialization signal line INT2, so that the first reset transistor T1 and the second reset transistor T7 receive initialization signals, respectively. The first initialization signal line INT1 is configured to input an initialization signal to the first reset transistor T1, and is connected to the first electrode of the first reset transistor T1. The second initialization signal line INT2 is configured to input an initialization signal to the second reset transistor T7, and is connected to the first electrode of the second reset transistor T7. The first initialization signal line INT1 is provided on a side of the second initialization signal line INT2 away from the control electrode of the first reset transistor T1, and the orthographic projection of the first initialization signal line INT1 on the base substrate at least partially overlaps with the orthographic projection of the active patterns on the base substrate. In the first direction N, the second initialization signal line INT2 is arranged between the first initialization signal line INT1 and the reset control signal line RST, and the orthographic projection of the second initialization signal line INT2 on the base substrate at least partially overlaps with the orthographic projection of the active patterns on the base substrate.

As illustrated in FIG. 8D, the first connection layer LY3 includes a fifth connection portion 807 and a sixth connection portion 808, one end of the fifth connection portion 807 is connected to the first electrode of the first reset transistor T1 through a via hole H81, and the other end of the fifth connection portion 807 is connected to the first initialization signal line INT1 through a via hole H82, thereby achieving the connection between the first electrode of the first reset transistor T1 and the first initialization signal line INT1.

As illustrated in FIG. 8D, one end of the sixth connection portion 808 is connected to the first electrode of the second reset transistor T7 through a via hole H83, and the other end of the sixth connection portion 808 is connected to the second initialization signal line INT2 through a via hole H84, thereby achieving the connection between the first electrode of the second reset transistor T7 and the second initialization signal line INT2. Thus, the first reset transistor T1 and the second reset transistor T7 can receive initialization signals, respectively.

Referring to FIG. 8A and FIG. 8E, after the second connection layer LY4 is provided on the display substrate, the second connection layer LY4 provides the data line DT for the pixel circuit, and the first electrode of the data writing transistor T4 is connected to the data line DT. The active units 805 in each row of active patterns 801 in the display substrate are all disconnected at the corresponding second conductor portion 802, and form a plurality of disconnection ends of a plurality of active units 805 arranged in the same row in the second direction Y in the disconnection region 806. As illustrated in FIG. 8E, in a connection region 810, a plurality of fifth disconnection ends 803 arranged in the same row of active units 805 are all connected to the second initialization signal line, and a plurality of sixth disconnection ends 804 are all connected to the first initialization signal line.

Thus, disconnecting the active pattern 801 in the pixel circuits at the third conductor portion 802 can enable the first reset transistor T1 and the second reset transistor T7 to receive different initialization signals, respectively, which can ensure the normal operation of the pixel circuit and reduce the risk of signal interference; in addition, disconnecting the active pattern 801 in the pixel circuit at the third conductor portion 802 can further enhance the uniformity of the ESD environment of the active sub-patterns in respective regions in the active pattern layer LY0, and reduce the Mura and other possible display defects caused by the ESD environment differences of the active sub-patterns.

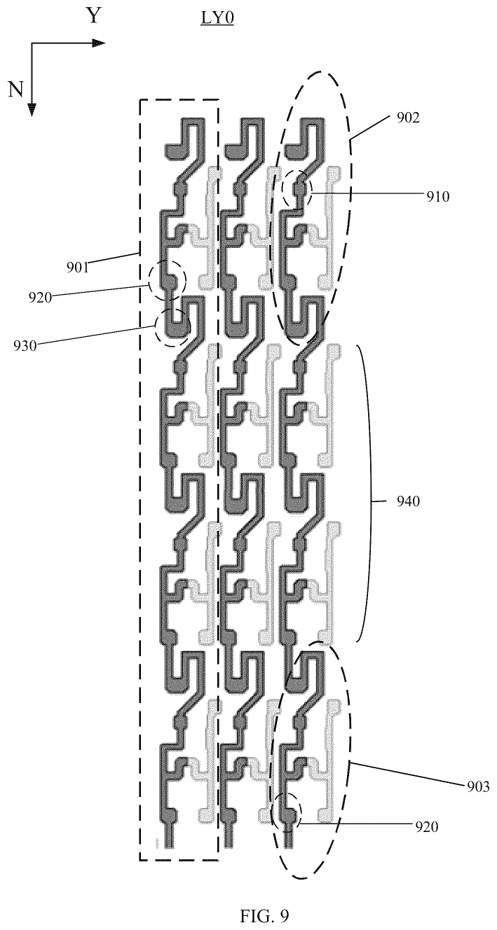

FIG. 9 is a schematic diagram of active patterns of a display substrate provided by an embodiment of the present disclosure.

For example, in some embodiments, a plurality of pixel circuits are arranged on the base substrate in an array. For example, as illustrated in FIG. 9, the plurality of pixel circuits in the display substrate include a plurality of active patterns 901, and at least one of the active patterns includes adjacent disconnection positions spaced apart by at least one row of the pixel circuits. That is, adjacent disconnection positions in the active patterns of the same column are spaced apart by at least one row of the pixel circuits.

Referring to FIG. 5A and FIG. 9, the active pattern layer LY0 includes a fourth disconnection position 910, a fifth disconnection position 920, or a sixth disconnection position 930, the fourth disconnection position 910 corresponds to the first conductor portion N1 in the pixel circuit of the display substrate, the fifth disconnection position 920 corresponds to the fourth conductor portion N4 in the pixel circuit of the display substrate, and the sixth disconnection position 930 corresponds to the connection position of the first electrode of the first reset transistor T1 and the first electrode of the second reset transistor T7 in the pixel circuit of the display substrate. In at least one column of pixel circuits along the first direction N, the disconnection positions of the active unit 902 and the active unit 903 may be different, for example, the active unit 902 is disconnected at the fourth disconnection position 910, and the active unit 903 is disconnected at the fifth disconnection position 920, therefore, the active unit 902 is spaced apart from the active unit 903 by at least one row of pixel circuits. For example, one or more rows of pixel circuits may be included between the active unit 902 and the active unit 903, and the specific amount of rows of pixel circuits spaced apart between two active units that are disconnected can be determined according to the actual patterning situation. For example, adjacent disconnection positions in the same column of active patterns are spaced apart by at least two rows of pixel circuits, and the embodiments of the present disclosure do not limit the amount of rows of pixel circuits spaced apart between two adjacent disconnection positions in the same column of active patterns. Of course, in some embodiments, the active units for the disconnection design may be selected in different rows or columns, and the present disclosure are not limited in this aspect.

Therefore, according to actual patterning requirements, the disconnection positions in the active pattern can be provided at non-adjacent active units in the same column, so that the patterning requirements and functional implementation requirements of the pixel circuit can be better met while ensuring and achieving the uniformity of the ESD environment of the active sub-patterns.

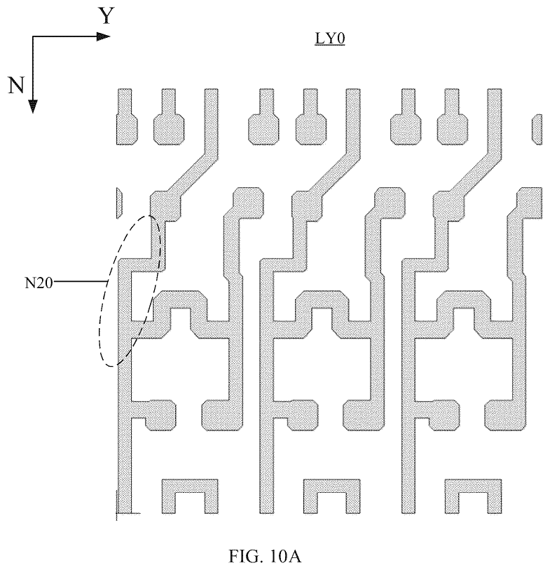

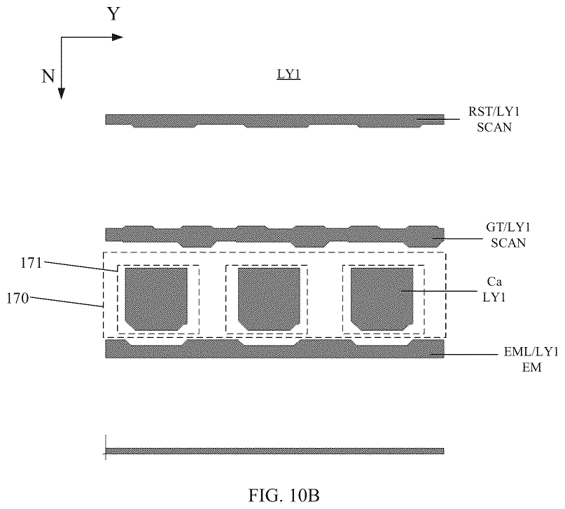

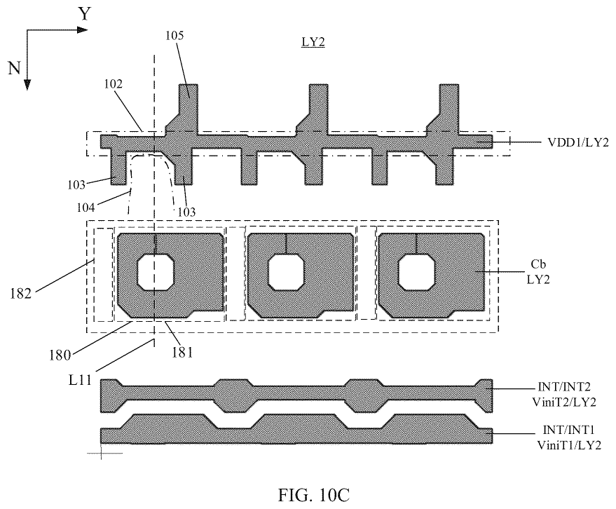

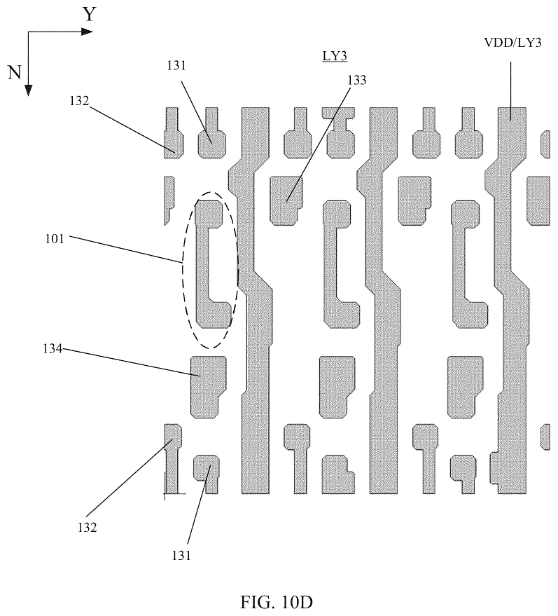

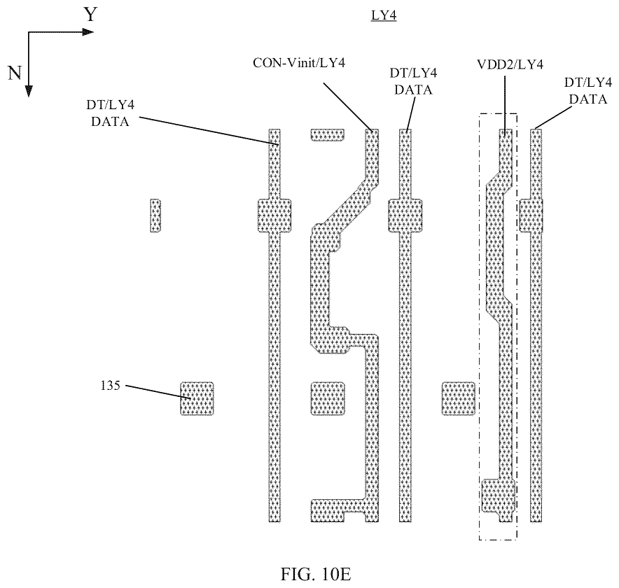

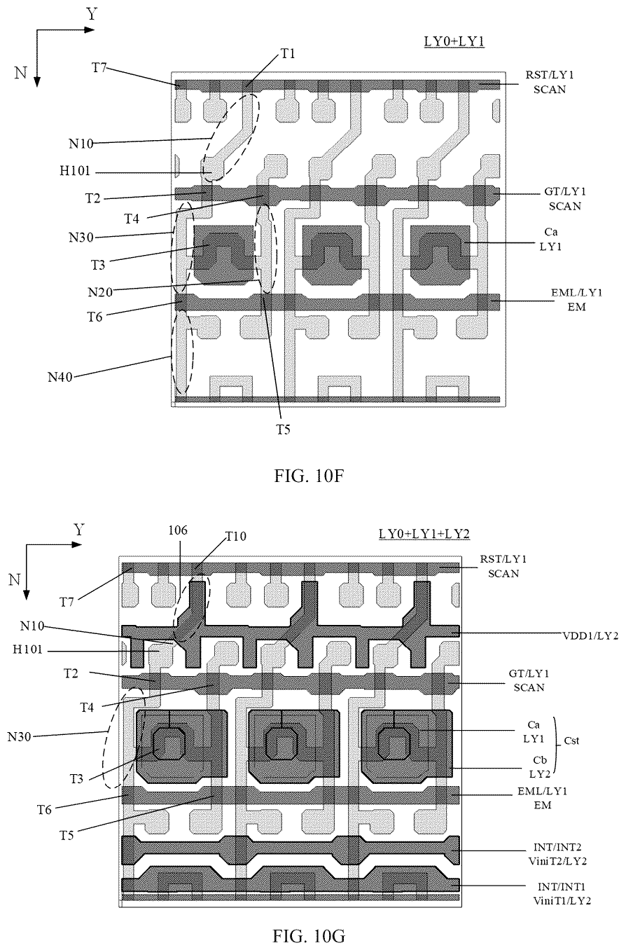

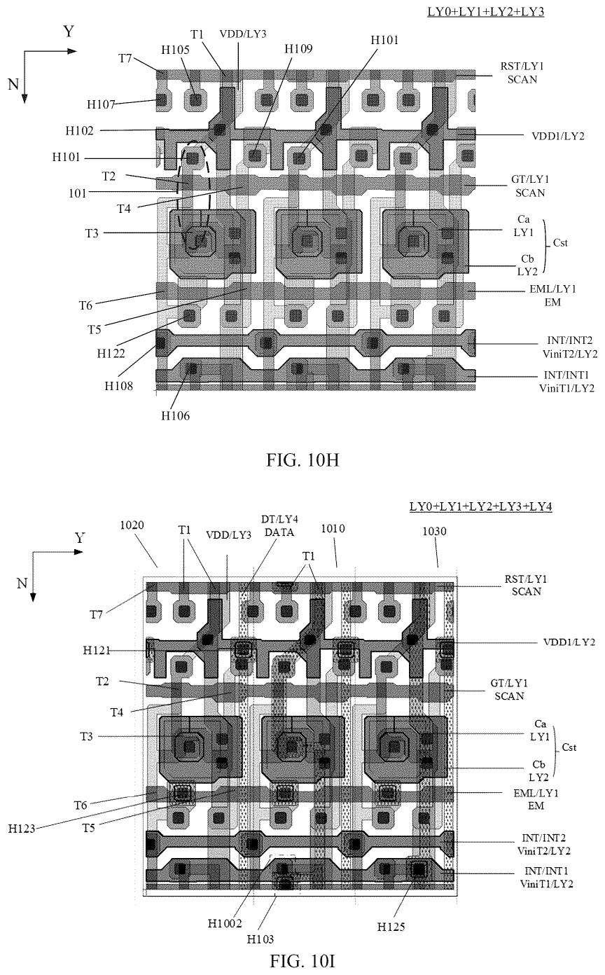

FIG. 10A is a plan view of active patterns of a display substrate provided by an embodiment of the present disclosure; FIG. 10B is a schematic diagram of a first conductive layer of a display substrate provided by an embodiment of the present disclosure; FIG. 10C is a schematic diagram of a second conductive layer of a display substrate provided by an embodiment of the present disclosure; FIG. 10D is a schematic diagram of a first connection layer of a display substrate provided by an embodiment of the present disclosure; FIG. 10E is a schematic diagram of a second connection layer of a display substrate provided by an embodiment of the present disclosure; FIG. 10F is a plan view of stacked layers of active patterns and a first conductive layer of a display substrate provided by an embodiment of the present disclosure; FIG. 10G is a plan view of stacked layers of active patterns, a first conductive layer, and a second conductive layer of a display substrate provided by an embodiment of the present disclosure; FIG. 10H is a plan view of stacked layers of active patterns, a first conductive layer, a second conductive layer, and a first connection layer of a display substrate provided by an embodiment of the present disclosure; and FIG. 10I is a plan view of stacked layers of active patterns, a first conductive layer, a second conductive layer, a first connection layer, and a second connection layer of a display substrate provided by an embodiment of the present disclosure.

Compared with the display substrates provided in the foregoing embodiments, the manufacturing process of the pixel circuits, the stacking relationship between layers, and the connection relationship and function of transistors in the display substrate illustrated in FIG. 10A-FIG. 10I are basically the same as those provided in the foregoing embodiments, and the disconnection position of the active pattern layer LY0 in the pixel circuit in the display substrate illustrated in FIG. 10A-FIG. 10I also corresponds to the third disconnection position 130 in FIG. 5B, and the similarities will not be repeated here. In the display substrates illustrated in FIG. 10A-FIG. 10I, the shape and wiring mode of the signal lines in the pixel circuit are optimized to reduce problems such as display crosstalk and improve the display effect of the display substrate.

FIG. 10A-FIG. 10I illustrate schematic diagrams of respective layers of a pixel circuit and the stacking relationship of the respective layers provided by some embodiments of the present disclosure. Referring to FIG. 10A, FIG. 10B and FIG. 10F, the pixel circuit includes the first reset transistor T1, the threshold compensation transistor T2, the data writing transistor T4, the second light-emitting control transistor T5, the first light-emitting control transistor T6, the second reset transistor T7, the driving transistor T3, and the storage capacitor Cst illustrated in FIG. 2B, the formation of the control electrode, the first electrode, and the second electrode of each transistor can refer to the foregoing embodiments, and the similarities will not be repeated here.

FIG. 10A-FIG. 10I further illustrate the control line GT, the light-emitting control signal line EML, the reset control signal line RST, and the first electrode Ca of the storage capacitor Cst that are provided in the first conductive layer LY1, and the control line GT, the light-emitting control signal line EML, and the reset control signal line RST all extend along the second direction Y. The second conductive layer LY2 provides the initialization signal line INT for the pixel circuit, and the first initialization signal line INT1 and the second initialization signal line INT2 are provided. In addition, the second electrode Cb of the storage capacitor Cst is provided in the second conductive layer LY2. The first connection layer LY3 provides the pixel circuit with the first voltage signal line VDD and a plurality of connection portions. For example, the plurality of connection portions can connect the transistors in the display substrate. The second connection layer LY4 provides the data line DT for the pixel circuit. The connection relationship and functional implementation principle of signal lines and data line can refer to the foregoing embodiments.

For example, as illustrated in FIG. 10F, the threshold compensation transistor T2 is a single-gate transistor.

Referring to FIG. 10D, FIG. 10F and FIG. 10H, the display substrate includes a first conductor portion N10 and a first connection portion 101, the second electrode of the first reset transistor T1 and the second electrode of the threshold compensation transistor T2 are connected to the first conductor portion N10, and formed integrally with the first conductor portion N10 in the active pattern layer LY0. The control electrode of the driving transistor T3 is connected to the first conductor portion N10 at a first via hole H101 through the first connection portion 101. The control line GT extends along the second direction. In the case where the threshold compensation transistor T2 is a single-gate transistor, the structural space requirement of the threshold compensation transistor T2 in the first direction N is lower, so that more space can be reserved between the reset control signal line RST and the control line GT, and enabling the layout of the display substrate more loose.

For example, the shape and trend of the first conductor portion N10 can be adjusted according to actual design requirements, and the position of the first via hole H101 on the first conductor portion N10 can also be changed. For example, as illustrated in FIG. 10G, the first via hole H101 can be provided at a position close to the control line GT.

For example, the display substrate illustrated in FIG. 10H includes an active pattern layer LY0, a first conductive layer LY1, a second conductive layer LY2, and a first connection layer LY3, the first conductive layer LY1 is located between the active pattern layer LY0 and the first connection layer LY3, and the control electrode of the threshold compensation transistor T2 is located in the first conductive layer LY1. The second conductive layer LY2 is located between the first conductive layer LY1 and the first connection layer LY3, the second conductive layer LY2 includes a first power supply signal line VDD1, and the first power supply signal line VDD1 extends along the second direction Y. The transistors in the pixel circuit further include a driving transistor T3, and in the first direction N, the first power supply signal line VDD1 is located on a side of the control electrode of the threshold compensation transistor T2 away from the driving transistor T3.

As illustrated in FIG. 10H, the first power supply signal line VDD1 is provided between the reset control signal line RST and the control line GT, a portion of the control line GT is served as the control electrode of the threshold compensation transistor 2, the driving transistor T3 is located on a side of the control electrode (control line GT) of the threshold compensation transistor T2 away from the first power supply signal line VDD1, and the reset control signal line RST does not overlap with the control line GT, thus reducing the risk of crosstalk with signals on the reset control signal line RST and the control line GT while well benefiting the layout space. In addition, the control line GT can be spaced apart from the reset control signal line RST by the first power supply signal line VDD1 extending along the second direction Y, thereby further reducing the risk of crosstalk with signals on the control line GT and the reset control signal line RST.

For example, referring to FIG. 10A, FIG. 10C and FIG. 10H, the first connection layer LY3 includes the first connection portion 101, and the control electrode of the driving transistor T3 is connected to the first conductor portion N10 at the first via hole H101 through the first connection portion 101. The first power supply signal line VDD1 includes a main body portion 102 and at least one isolation portion 103, the main body portion 102 extends along the second direction Y, the at least one isolation portion 103 is connected to the main body portion 102 and extends along the first direction N, and the first via hole H101 is located in the surrounded region 104 formed by the at least one isolation portion 103 and the main body portion 102.

Referring to FIG. 10C and FIG. 10H, the surrounded region 104 formed by the at least one isolation portion 103 and the main body portion 102 is an unenclosed region, and the at least one isolation portion 103 does not overlap with the control line GT In the first direction N, the surrounded region 104 is substantially coincident with a centerline of the control electrode of the driving transistor T3, which is indicated by L11 in FIG. 10C, that is, the control electrode of the driving transistor T3 right faces the surrounded region 104. The first connection portion 101 extends into but does not pass through the surrounded region 104 to connect the control electrode of the driving transistor T3 with the first conductor portion N10 at the first via hole H101. A side of the first via hole H101 away from the driving transistor T3 in the first direction N and both sides of the first via hole H101 in the second direction Y are surrounded by the surrounded region 104, so the providing of the surrounded region 104 can isolate the signals on both sides of the first via hole H101 and on the side of the first via hole H101 away from the driving transistor T3 to reduce the risk of crosstalk between the signal lines connected through the first via hole H101. For example, referring to FIG. 101, the providing of the surrounded region 104 can also reduce mutual influences, such as crosstalk, between signal lines connected through the first via hole H101 and the data line DT.

For example, referring to FIG. 10C, FIG. 10G and FIG. 10H, the first power supply signal line VDD1 further includes at least one shielding portion 105, the at least one shielding portion 105 is connected to the main body portion 102 and extends along the first direction N, the at least one shielding portion 105 is provided on a side of the main body portion 102 away from the isolation portion 103, and the orthographic projection of the at least one shielding portion 105 on the base substrate at least partially overlaps with the orthographic projection of the first conductor portion N10 on the base substrate.

Referring to FIG. 10C, FIG. 10G and FIG. 10H, the first power supply signal line VDD1 between the reset control signal line RST and the control line GT generally extends along the second direction Y, and the at least one shielding portion 105 is designed according to the wiring trend of the first conductor portion N10 and covers the first conductor portion N10 as much as possible, thus forming a shielding region 106, and the shielding region 106 does not overlap with the via hole structures on both sides of the shielding region 106. The shielding portion 105 is used to shield the first conductor portion N10 (for example, a portion other than the region of the first via hole H101), which is beneficial to the signal shielding and layout design of the display substrate.

Referring to FIG. 10E and FIG. 10I, the display substrate is provided with a first conductive layer LY1, a second conductive layer LY2, and a second connection layer LY4, and the first conductive layer LY1, the second conductive layer LY2, and the second connection layer LY4 are arranged sequentially along the direction away from the base substrate. The second connection layer LY4 is located on a side of the first connection layer LY3 away from the base substrate, the second connection layer LY4 includes an initialization connection signal line CON-Vinit, and the initialization connection signal line CON-Vinit extends along the first direction N. The second conductive layer LY2 includes a first initialization signal line INT1, and the first initialization signal line INT1 extends along the second direction Y. The plurality of transistors include a first reset transistor T1, a first electrode of the first reset transistor T1 is connected to the first initialization signal line INT1, and the first initialization signal line INT1 is connected to the initialization connection signal line CON-Vinit.

Referring to FIG. 10E and FIG. 10I, the second connection layer LY4 includes a plurality of data lines DT and a plurality of connection portions, and in the second direction, the initialization connection signal line CON-Vinit is provided between two data lines DT. The first initialization signal line INT1 extends along the second direction, and the first electrode of the first reset transistor T1 is connected to the first initialization signal line INT1 through a via hole H1002. The initialization connection signal line CON-Vinit is connected to the first initialization signal line INT1 through a via hole H103, so that the loading of the first initialization signal line INT1 can be reduced by the initialization connection signal line CON-Vinit, thereby increasing the pixel charging rate.

For example, as illustrated in FIG. 10I, the display substrate includes a plurality of pixel circuits corresponding to a plurality of sub-pixels. For example, the plurality of pixel circuits include a plurality of pixel circuit groups. Each pixel circuit group includes a first pixel circuit sub-group 1010 and a second pixel circuit sub-group, and the second pixel circuit sub-group and the first pixel circuit sub-group 1010 are arranged sequentially along the second direction, the first pixel circuit sub-group 1010 includes a plurality of first pixel circuit arranged sequentially along the first direction, the second pixel circuit sub-group includes a plurality of second pixel circuits and a plurality of third pixel circuits arranged sequentially along the first direction, and the initialization connection signal line CON-Vinit is provided in the first pixel circuit sub-group 1010 to facilitate the layout design and improve the display effect.

For example, the second pixel circuit sub-group among the plurality of pixel circuit groups includes a second pixel circuit sub-group 1020 and a second pixel circuit sub-group 1030, the second pixel circuit sub-group 1020 includes a plurality of second pixel circuits, and the second pixel circuit sub-group 1030 includes a plurality of third pixel circuits. For example, the first pixel circuit is configured to drive the green sub-pixel to emit light, the second pixel circuit is configured to drive the red sub-pixel to emit light, and the third pixel circuit is configured to drive the blue sub-pixel to emit light. In some embodiments of the present disclosure, the corresponding relationship between respective pixel circuits and the sub-pixels can be flexibly set according to actual design requirements, and the embodiments of the present disclosure are not limited in this aspect. For example, the second pixel circuit 1020 may be configured to drive the green sub-pixel to emit light, and the third pixel circuit 1030 may be configured to drive the red sub-pixel to emit light.

Referring to FIG. 10D, FIG. 10F, FIG. 10E and FIG. 10H, the display substrate is provided with a first connection portion 101, the second electrode of the first reset transistor T1, the second electrode of the threshold compensation transistor T2, and the control electrode of the driving transistor T3 are connected to the first connection portion 101 at the first via hole H101, and the orthographic projection of the initialization connection signal line CON-Vinit on the substrate at least partially overlaps with the orthographic projection of the first connection portion 101 on the substrate.

Referring to FIG. 10D, FIG. 10E, FIG. 10F and FIG. 10H, the initialization connection signal line CON-Vinit covers the first connection portion 101 at the first via hole H101, thereby weakening the influence of the signal lines connected at the first via hole H101 from the signals around and above the first via hole H101.

For example, referring to FIG. 10B, FIG. 10C, FIG. 10F and FIG. 10G, the first conductive layer LY1 includes a first capacitor portion 170, the first capacitor portion 170 includes a plurality of first capacitor sub-portions 171, and the plurality of first capacitor sub-portions 171 are arranged spaced apart from each other along the second direction Y. The second conductive layer LY2 includes a second capacitor portion 180, the second capacitor portion 180 includes a plurality of capacitor islands 181, the plurality of capacitor islands 181 are spaced apart from each other along the second direction Y, and each first capacitor sub-portion 171 is provided opposite to at least part of each capacitor island 181.

Referring to FIG. 10B, FIG. 10C, FIG. 10F and FIG. 10G, first capacitor sub-portions 171 are in one-to-one correspondence to capacitor islands 181, the first capacitor sub-portion 171 is served as the first electrode Ca of the storage capacitor, the capacitor island 181 is served as the second electrode Cb of the storage capacitor, and the first capacitor sub-portion 171 and the capacitor island 181 are arranged opposite to each other to form the storage capacitor Cst. The first electrode Ca of the storage capacitor is also served as the control electrode of the driving transistor T3.

As illustrated in FIG. 10F, the display substrate further includes a second conductor portion N20, a third conductor portion N30, and a fourth conductor portion N40. The first electrode of the driving transistor T3, the second electrode of the data writing transistor T4, and the second electrode of the second light-emitting control transistor T5 are connected to the second conductor portion N20, and are integrally formed with the second conductor portion N20 in the active pattern layer LY0. The first electrode of the threshold compensation transistor T2, the second electrode of the driving transistor T3, and the first electrode of the first light-emitting control transistor T6 are connected to the third conductor portion N30, and are integrally formed with the third conductor portion N30 in the active pattern layer LY0. The second electrode of the first light-emitting control transistor T6 and the second electrode of the second reset transistor T7 are connected to the fourth conductor portion N40 and integrally formed with the fourth conductor portion N40 in the active pattern layer LY0.

As illustrated in FIG. 10C, the plurality of capacitor islands 181 in the second capacitor portion 180 are spaced apart from each other and are not connected to each other. As illustrated in FIG. 10C, a spacing region 182 is provided between adjacent capacitor islands 181, the dimension of the spacing region 182 is designed according to the requirements of actual layout design, and the embodiments of the present disclosure are not limited in this aspect. Referring to FIG. 10C and FIG. 10G, in the case where the spacing region 182 is provided between adjacent capacitor islands 181, the orthographic projection of the spacing region 182 on the base substrate at least partially overlap with the orthographic projection of the third conductor portion N30 on the base substrate, while the orthographic projection of the capacitor island 181 on the base substrate does not overlap with the orthographic projection of the third conductor portion N30 on the base substrate. Therefore, the parasitic capacitance between the capacitor island 181 and the third conductor portion N30 can be reduced by enabling the plurality of capacitor islands 181 to be spaced apart from each other, thereby reducing the impact on the stable operation of the pixel circuit.

Referring to FIG. 10D, FIG. 10E, FIG. 10H and FIG. 10I, the first connection layer LY3 further includes a connection portion 131, a connection portion 132, a connection portion 133, and a connection portion 134, and the plurality of connection portions can connect the transistors in the display substrate.

Referring to FIG. 10D, FIG. 10E, FIG. 10H and FIG. 10I, one end of the connection portion 131 is connected to the first electrode of the first reset transistor T1 through a via hole H105, and the other end of the connection portion 131 is connected to the first initialization signal line INT1 through a via hole H106, that is, the connection between the first electrode of the first reset transistor T1 and the first initialization signal line INT1 is achieved through the connection portion 131.

Referring to FIG. 10D, FIG. 10E, FIG. 10H and FIG. 10I, one end of the connection portion 132 is connected to the first electrode of the second reset transistor T7 through a via hole H107, and the other end of the connection portion 132 is connected to the second initialization signal line INT2 through a via hole H108, that is, the connection between the first electrode of the second reset transistor T7 and the second initialization signal line INT2 is achieved through the connection portion 132.

Referring to FIG. 10D, FIG. 10E, FIG. 10H and FIG. 10I, one end of the connection portion 133 is connected to the first electrode of the data writing transistor T4 through a via hole H109, and the other end of the connection portion 132 is connected to the data line DT through a via hole H121, that is, the connection between the first electrode of the data writing transistor T4 and the data line DT is achieved through the connection portion 133, that is, the connection portion 133 is served as an intermediate transfer connector to connect the first electrode of the data writing first transistor T4 and data line DT.

Referring to FIG. 10D, FIG. 10E, FIG. 10H and FIG. 10I, one end of the connection portion 134 is connected to the second electrode of the first light-emitting control transistor T6 through a via hole H122, and the other end of the connection portion 134 is connected to a connection portion 135 in the second connection layer LY4 through a via hole H123, and is further connected to the first electrode E1 (not illustrated in the figures) of the light-emitting element through the via hole H123, that is, the connection portion 134 and the connection portion 135 are served as two intermediate transfer connectors to connect the second electrode of the first light-emitting control transistor T6 and the first electrode E1 of the light-emitting element.

Referring to FIG. 10D, FIG. 10E, FIG. 10H and FIG. 10I, in the third pixel circuit, the first voltage signal line VDD extends along the first direction, and the first power supply signal line VDD1 is connected to the first voltage signal line VDD through a via hole H102, thereby reducing the loading of the first voltage signal line VDD and improving the operation performance of the pixel circuit. The second connection layer LY4 further includes a second power supply signal line VDD2, the second power supply signal line VDD2 extends along the first direction, and the wiring trend of the second power supply signal line VDD2 is as close as possible to the first voltage signal line VDD in the first connection layer LY3. As illustrated in FIG. 10I, along the direction perpendicular to the base substrate, the second power supply signal line VDD2 covers the first voltage signal line VDD, and is connected to the first voltage signal line VDD through a via hole H125. Therefore, the providing of the second power supply signal line VDD2 can reduce the loading of the first voltage signal line VDD, which is beneficial to the effective operation of the pixel circuit.

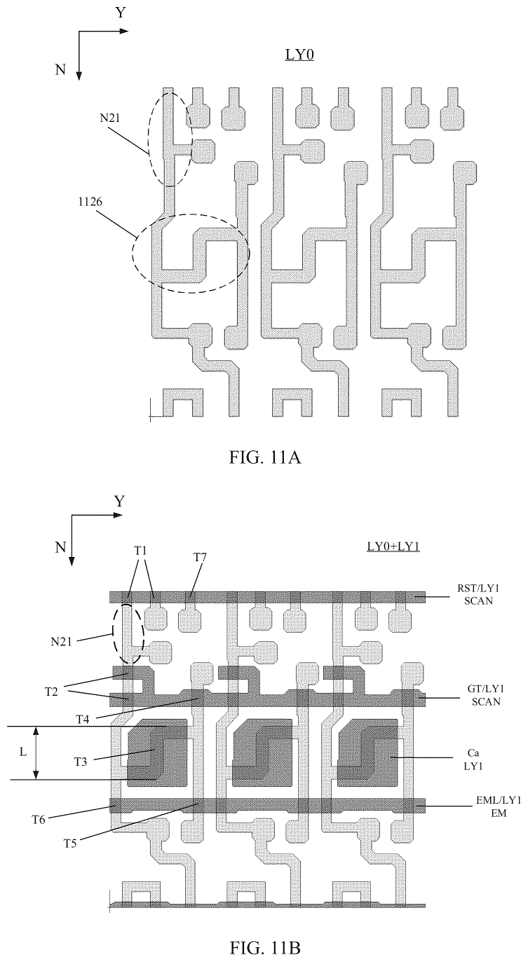

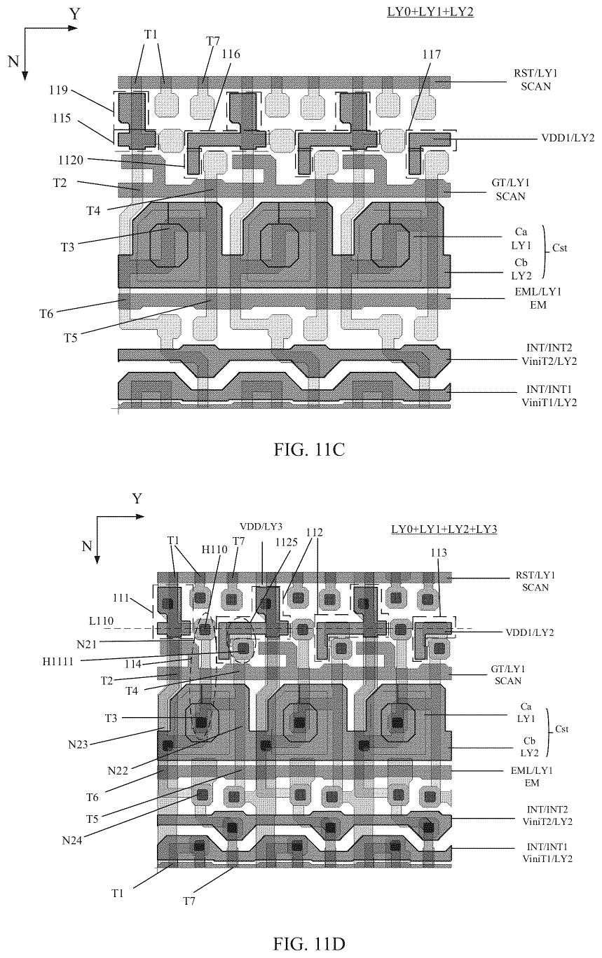

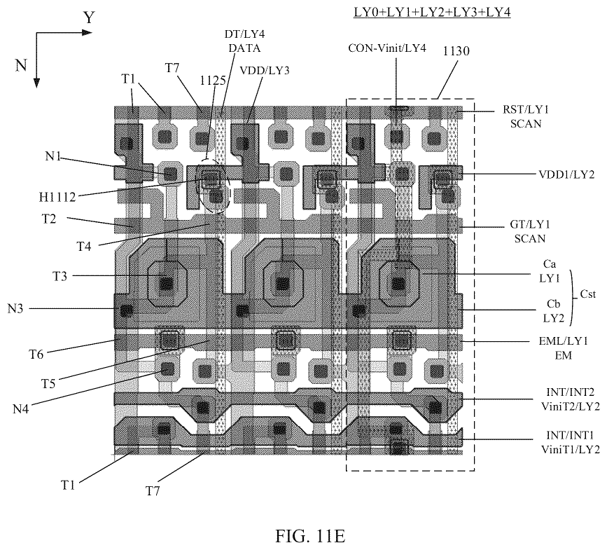

FIG. 11A is a plan view of active patterns of a display substrate provided by an embodiment of the present disclosure. FIG. 11B is a plan view of stacked layers of active patterns and a first conductive layer of a display substrate provided by an embodiment of the present disclosure. FIG. 11C is a plan view of stacked layers of active patterns, a first conductive layer, and a second conductive layer of a display substrate provided by an embodiment of the present disclosure. FIG. 11D is a plan view of stacked layers of active patterns, a first conductive layer, a second conductive layer, and a first connection layer of a display substrate provided by an embodiment of the present disclosure. FIG. 11E is a plan view of stacked layers of active patterns, a first conductive layer, a second conductive layer, a first connection layer, and a second connection layer of a display substrate provided by an embodiment of the present disclosure.

Compared with the display substrates provided by the embodiments of FIG. 10A to FIG. 10I, the manufacturing process of the pixel circuits, the stacking relationship between layers, and the connection relationship and function of transistors in the display substrate illustrated in FIG. 11A-FIG. 11E are basically the same as those illustrated in FIG. 10A to FIG. 10I, and the disconnection position of the active pattern layer LY0 in the pixel circuit in the display substrate illustrated in FIG. 11A-FIG. 11E also corresponds to the third disconnection position 130 in FIG. 5B, and the similarities will not be repeated here. The difference is that in the display substrates illustrated in FIG. 11A-FIG. 11E, the shape and wiring mode of the signal lines in the pixel circuit are optimized in another way to reduce problems such as display crosstalk and improve the display effect of the display substrate.

FIG. 11A-FIG. 11E illustrate schematic diagrams of respective layers of a pixel circuit and the stacking relationship of the respective layers provided by some embodiments of the present disclosure, the pixel circuit includes the first reset transistor T1, the threshold compensation transistor T2, the data writing transistor T4, the second light-emitting control transistor T5, the first light-emitting control transistor T6, the second reset transistor T7, the driving transistor T3, and the storage capacitor Cst that are illustrated in FIG. 2B, the formation of the control electrode, the first electrode, and the second electrode of each transistor can refer to the foregoing embodiments, and the similarities will not be repeated here.

FIG. 11A-FIG. 11E further illustrate the control line GT, the light-emitting control signal line EML, the reset control signal line RST and the first electrode Ca of the storage capacitor Cst that are provided in the first conductive layer LY1, and the control line GT, the light-emitting control signal line EML, and the reset control signal line RST all extend along the second direction Y. The second conductive layer LY2 provides the initialization signal line INT for the pixel circuit, and the first initialization signal line INT1 and the second initialization signal line INT2 are provided. In addition, the second electrode Cb of the storage capacitor Cst is provided in the second conductive layer LY2. The first connection layer LY3 provides the pixel circuit with the first voltage signal line VDD and a plurality of connection portions. For example, the plurality of connection portions can connect the transistors in the display substrate. The second connection layer LY4 provides the data line DT for the pixel circuit. The connection relationship and functional implementation principle of signal lines and data line can refer to the foregoing embodiments.

For example, referring to FIG. 11A-FIG. 11E, the display substrate includes a first conductive layer LY1 and a second conductive layer LY2, and the first conductive layer LY1, the second conductive layer LY2, and the first connection layer LY3 are arranged sequentially along the direction away from the base substrate. The second conductive layer LY2 includes a first power supply signal line VDD1, the first power supply signal line VDD1 includes a plurality of power supply portions, such as a power supply portion 111, a power supply portion 112, and a power supply portion 113, and the plurality of power supply portions are arranged along the second direction Y and arranged spaced apart from each other. The conductor region of the display substrate includes a first conductor portion N21, the transistors in the display substrate include a first reset transistor T1, a threshold compensation transistor T2, and a driving transistor T3, and the first conductor portion N21 is connected to the second electrode of the first reset transistor T1 and the second electrode of the threshold compensation transistor T2, respectively. The plurality of connection portions in the display substrate include a first connection portion 114, the control electrode of the driving transistor T3 is connected to the first conductor portion N21 at a first via hole H10 through the first connection portion 114, and the first via hole H110 is located between adjacent power supply portions.

As illustrated m FIG. 11D, the orthographic projection of the first via hole H110 on the base substrate does not overlap with the orthographic projection of each power supply portion on the base substrate, and in the second direction Y, each power supply portion is provided with a horizontal centerline L110, and the first via hole H110 is substantially provided on the horizontal centerline L110.

Referring to FIG. 11D and FIG. 11E, the power supply portions located on both sides of the first via hole H110 can isolate and shield the signal line connected at the first via hole H110 by providing the first via hole H110 between adjacent power supply portions. For example, in the second direction Y, a data line DT is provided on a side of the first via hole H110 away from the threshold compensation transistor T2, and the power supply portion 112 can isolate the signal line and the data line at the first via hole H110 to reduce the signal on the data line from interfering with the signal at the first via hole, thereby optimizing the operation performance of the pixel circuit.

For example, referring to FIG. 11C, FIG. 11D and FIG. 11E, at least one power supply portion includes a main body portion and at least one isolation portion, the at least one isolation portion is connected to the main body portion and extends along the first direction N. and the first via hole H110 is located between the main body portion and the isolation portion that are adjacent to each other.

Referring to FIG. 11D and FIG. 11E, the first connection portion includes a connection portion 1125, one end of the connection portion 1125 is connected to the first electrode of the data writing transistor T4 through a via hole H1101, and the other end of the connection portion 1125 is connected to the data line DT through a via hole H1112, that is, the connection between the first electrode of the data writing transistor T4 and the data line DT is achieved through the connection portion 1125. That is, the connection portion 1125 is served as an intermediate transfer connector to connect the first electrode of the data writing transistor T4 and the data line DT.

Referring to FIG. 11C and FIG. 11D, the power supply portion 111 includes a main body portion 115 and an isolation portion (not illustrated), the power supply portion 112 includes a main body portion 116 and an isolation portion 1120, and the power supply portion 113 includes a main body portion 117 and an isolation portion 1120. In each power supply portion, by providing the isolation portion 1120, the signal line (first connection portion) at the first via hole H110 can be isolated from the data line, and the signal line at the first via hole H110 can be isolated and shielded on the left and right sides to reduce the signal on the data line DT from interfering with the signal at the first via hole H110, thereby optimizing the operation performance of the pixel circuit.

Referring to FIG. 11A, FIG. 11C and FIG. 11D, the first power supply signal line VDD1 further includes at least one shielding portion 119, the at least one shielding portion 119 is connected to respective main body portions and extends along the first direction N, the at least one shielding portion 119 is provided on a side of the main body portion away from the isolation portion 1120, and the orthographic projection of the at least one shielding portion 119 on the base substrate at least partially overlaps with the orthographic projection of the first conductor portion N21 on the base substrate.

Referring to FIG. 11B. FIG. 11C and FIG. 11D, the first power supply signal line VDD1 between the reset control signal line RST and the control line GT generally extends along the second direction Y, and the at least one shielding portion 119 is designed according to the wiring trend of the first conductor portion N12 and covers the first conductor portion N12 as much as possible, and the shielding portion 119 does not overlap with the via hole structures at a periphery of the shielding portion. The shielding portion 119 is used to shield the first conductor portion N12 (for example, a portion other than the region of the first via hole H110), which is beneficial to the signal shielding of the pixel circuit and enabling the layout space relatively more loose.

For example, referring to FIG. 11A-FIG. 11C, the channel region 1126 of the driving transistor T3 in the display substrate is in a shape of a polyline. Compared with other shapes in some embodiments (for example, an A-shaped active pattern), the channel region 1126 designed to be in a shape of a polyline can reduce the dimension L of the active pattern of the channel region of the driving transistor T3 in the first direction N, which is beneficial to enabling the patterning space of the display substrate more loose and increasing the utilization rate of the patterning space.

For example, the channel region of the driving transistor T3 is designed to be in a shape of a character “Z”, so that the dimension L of the active pattern of the channel region of the driving transistor T3 in the first direction N can be reduced while the driving transistor T3 can operate normally, and the Z-shaped active pattern is easy to achieve and the operation cost is low.

For example, in some embodiments of the present disclosure, it is not limited to design the active pattern of the channel region of the driving transistor T3 as a shape of a character “Z”, any shape that can reduce the dimension L of the active pattern of the channel region of the driving transistor T3 in the first direction N. and is beneficial to enabling the patterning space of the display substrate more loose can be adopted, and the embodiments of the present disclosure are not limited in this aspect.

For example, referring to FIG. 11D and FIG. 11E, the first conductive layer LY1, the second conductive layer LY2, and the second connection layer LY4 in the display substrate are arranged sequentially along the direction away from the base substrate, the second connection layer LY4 is located on a side of the first connection layer LY3 away from the base substrate, the second connection layer LY4 includes an initialization connection signal line CON-Vinit, and the initialization connection signal line CON-Vinit extends along the first direction N. The second conductive layer LY2 includes a first initialization signal line INT1, and the first initialization signal line INT1 extends along the second direction Y. The plurality of transistors include a first reset transistor T1, the first electrode of the first reset transistor T1 is connected to the first initialization signal line INT1, and the first initialization signal line INT1 is connected to the initialization connection signal line CON-Vinit.

Compared with the display substrate in FIG. 10E, the shape trend of the initialization connection signal line CON-Vinit in FIG. 11E is different, but the initialization connection signal line CON-Vinit is also provided in the pixel circuit that drives the green sub-pixel to emit light, that is, the initialization connection signal line CON-Vinit is provided in the sub-pixel circuit 1130. The initialization connection signal line CON-Vinit is connected to the first initialization signal line INT1, thereby reducing the loading of the first initialization signal line INT1 and increasing the pixel charging rate.

For example, referring to FIG. 11C-FIG. 11D, the orthographic projection of the initialization connection signal line CON-Vinit on the base substrate at least partially overlaps with the orthographic projection of the first connection portion 114 on the base substrate, and the initialization connection signal line CON-Vinit covers the first connection portion 114 at the first via hole H110, thereby weakening the influence of the signal lines connected at the first via hole H110 from the signals around and above the first via hole H110.

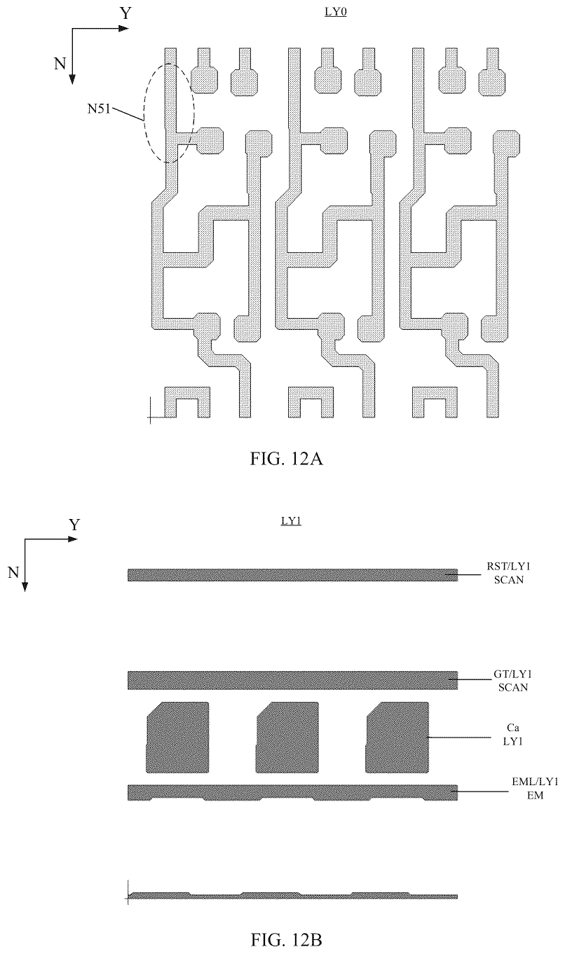

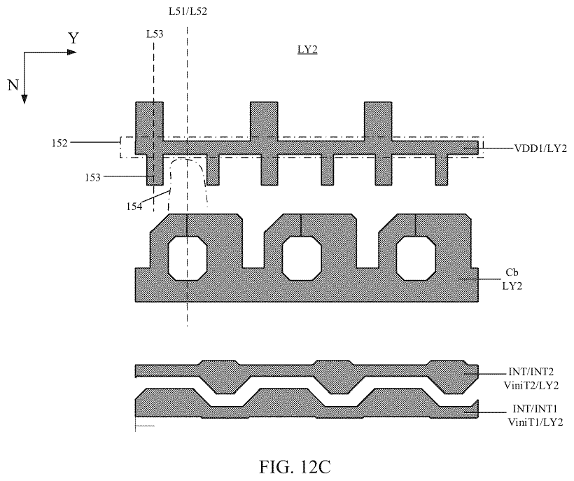

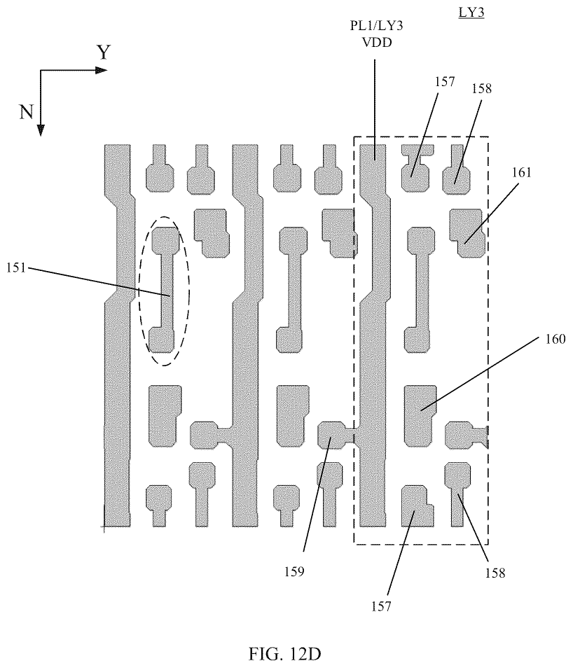

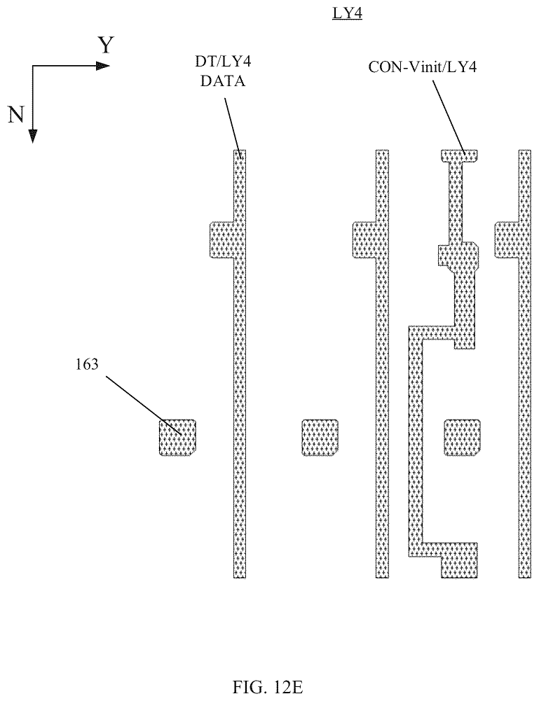

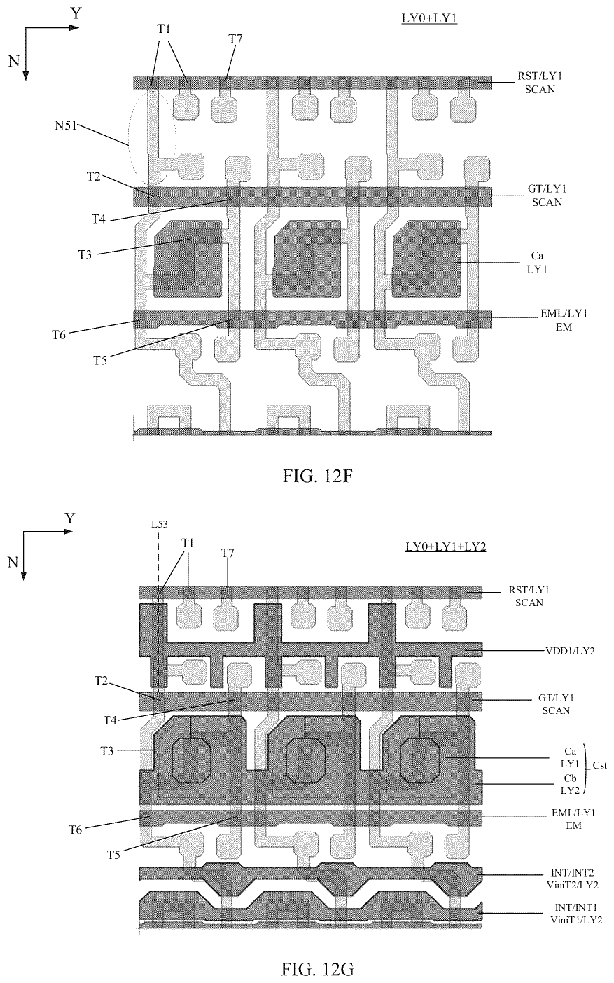

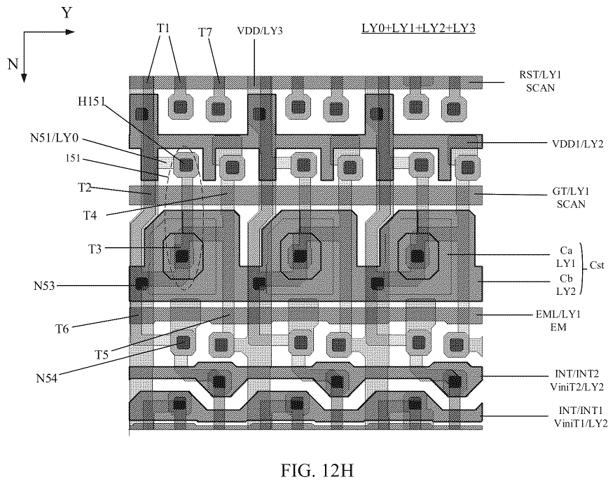

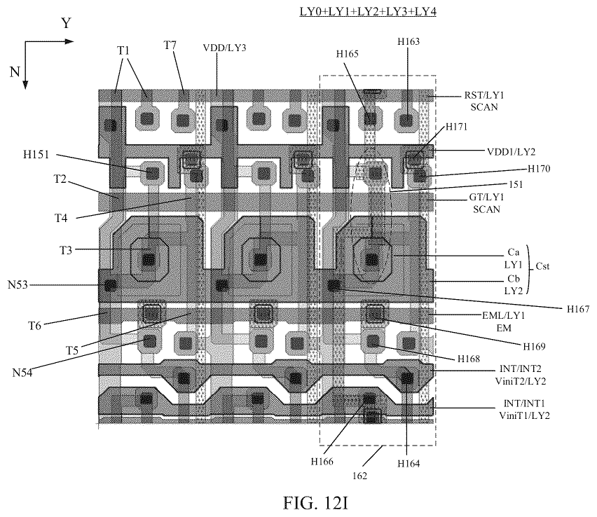

FIG. 12A is a plan view of active patterns of a display substrate provided by an embodiment of the present disclosure. FIG. 12B is a schematic diagram of a first conductive layer of a display substrate provided by an embodiment of the present disclosure. FIG. 12C is a schematic diagram of a second conductive layer of a display substrate provided by an embodiment of the present disclosure. FIG. 12D is a schematic diagram of a first connection layer of a display substrate provided by an embodiment of the present disclosure. FIG. 12E is a schematic diagram of a second connection layer of a display substrate provided by an embodiment of the present disclosure. FIG. 12F is a plan view of stacked layers of active patterns and a first conductive layer of a display substrate provided by an embodiment of the present disclosure. FIG. 12G is a plan view of stacked layers of active patterns, a first conductive layer, and a second conductive layer of a display substrate provided by an embodiment of the present disclosure. FIG. 12H is a plan view of stacked layers of active patterns, a first conductive layer, a second conductive layer, and a first connection layer of a display substrate provided by an embodiment of the present disclosure. FIG. 12I is a plan view of stacked layers of active patterns, a first conductive layer, a second conductive layer, a first connection layer, and a second connection layer of a display substrate provided by an embodiment of the present disclosure.

Compared with the display substrates provided by the embodiments in FIG. 11A-FIG. 11E, the manufacturing process of the pixel circuits, the stacking relationship between layers, and the connection relationship and function of transistors in the display substrate illustrated in FIG. 12A-FIG. 12I are basically the same as those in the display substrate illustrated in FIG. 11A-FIG. 11E, and the disconnection position of the active pattern layer LY0 in the pixel circuit in the display substrate illustrated in FIG. 12A-FIG. 12I also corresponds to the third disconnection position 130 in FIG. 5B, and the similarities will not be repeated here. The difference is that in the display substrates illustrated in FIG. 12A-FIG. 12I, the shape and wiring mode of the signal lines in the pixel circuit are optimized in another way to reduce problems such as display crosstalk and improve the display effect of the display substrate.

For example, as illustrated in FIG. 12F, the threshold compensation transistor T2 is a single-gate transistor.

Referring to FIG. 12A, FIG. 12D, FIG. 12F and FIG. 12H, the display substrate includes a first conductor portion N51 and a first connection portion 151, the second electrode of the first reset transistor T1 and the second electrode of the threshold compensation transistor T2 are connected to the first conductor portion N51, and formed integrally with the first conductor portion N51 in the active pattern layer LY0. The control electrode of the driving transistor T3 is connected to the first conductor portion N51 at a first via hole H151 through the first connection portion 151. The control line GT extends along the second direction, and the threshold compensation transistor T2 adopting a single-gate structure requires less structural space in the first direction N, so that more space can be reserved between the reset control signal line RST and the control line GT, and enabling the layout of the display substrate more loose.

For example, the shape and trend of the first conductor portion N51 can be adjusted according to actual design requirements, and the position of the first via hole H151 on the first conductor portion N51 can also be changed.

For example, the display substrate illustrated in FIG. 12H includes an active pattern layer LY0, a first conductive layer LY1, a second conductive layer LY2, and a first connection layer LY3, the first conductive layer LY1 is located between the active pattern layer LY0 and the first connection layer LY3, the first conductive layer LY1 includes a gate line, that is, a control line GT, and the control electrode of the threshold compensation transistor T2 is connected to the control line GT. The second conductive layer LY2 is located between the first conductive layer LY1 and the first connection layer LY3, the second conductive layer LY2 includes a first power supply signal line VDD1, the first power supply signal line VDD1 extends along the second direction Y, and in the first direction N, the first power supply signal line VDD1 is located on a side of the control line GT away from the threshold compensation transistor T2.

As illustrated in FIG. 12H, the first power supply signal line VDD1 is provided between the reset control signal line RST and the control line GT, and does not overlap with the reset control signal line RST and the control line GT, thus reducing the risk of crosstalk with signals on the reset control signal line RST and the control line GT while well benefiting the layout space. In addition, the control line GT can be spaced apart from the reset control signal line RST by the first power supply signal line VDD1 extending along the second direction Y, thereby further reducing the risk of crosstalk with signals on the control line GT and the reset control signal line RST.

Referring to FIG. 12C and FIG. 12H, the first connection layer LY3 includes the first connection portion 151, and the control electrode of the driving transistor T3 is connected to the first conductor portion N51 at the first via hole H151 through the first connection portion 151. The first power supply signal line VDD1 includes a main body portion 152 and at least one isolation portion 153, the main body portion 152 extends along the second direction Y, the at least one isolation portion 153 is connected to the main body portion 152 and extends along the first direction N. and the first via hole H151 is located in a surrounded region 154 formed by the at least one isolation portion 153 and the main body portion 152.

Referring to FIG. 12C and FIG. 12H, the surrounded region 154 formed by the at least one isolation portion 153 and the main body portion 152 is an unenclosed region, and the at least one isolation portion 153 does not overlap with the control line GT. In the first direction N, a centerline L51 of the surrounded region 154 is substantially coincident with a centerline L52 of the control electrode of the driving transistor T3. The isolation portions 153 and the control electrode of the driving transistors T3 are alternately arranged, and a centerline L53 of the isolation portion 153 does not coincide with the centerline L52 of the control electrode of the driving transistor T3. The first connection portion 151 extends into but does not pass through the surrounded region 154 to connect the control electrode of the driving transistor T3 with the first conductor portion N51 at the first via hole H151. A side of the first via hole H151 away from the driving transistor T3 in the first direction N and both sides of the first via hole H151 in the second direction Y are surrounded by the surrounded region 154, so the providing of the surrounded region 154 can isolate the signals on both sides of the first via hole H151 and on the side of the first via hole H151 away from the driving transistor T3 to reduce the risk of crosstalk between the signal lines connected through the first via hole H151. For example, referring to FIG. 12I, two adjacent data lines DT are provided on the outside of the surrounded region 154 away from the first via hole H151, so the providing of the surrounded region 154 can reduce mutual influences, such as crosstalk, between signal lines connected through the first via hole H151 and the data line DT.

For example, referring to FIG. 12C, FIG. 12F and FIG. 12G, the first power supply signal line VDD1 further includes at least one shielding portion 155, the at least one shielding portion 155 is connected to the main body portion 152 and extends along the first direction N, the at least one shielding portion 155 is provided on a side of the main body portion 152 away from the isolation portion 153, and the orthographic projection of the at least one shielding portion 155 on the base substrate at least partially overlaps with the orthographic projection of the first conductor portion N51 on the base substrate.

Referring to FIG. 12C, FIG. 12F, FIG. 12G and FIG. 12H, the first power supply signal line VDD1 between the reset control signal line RST and the control line GT generally extends along the second direction Y, and the first power supply signal line VDD1 is continuously provided. The extending directions of the isolation portion 153, the shielding portion 155, and the first conductor portion N51 are identical to each other, with basically the same wiring trend, and the centerlines are basically coincident, as illustrated by L53 in FIG. 12G. The shielding portion 155 covers the first conductor portion N51 as much as possible, and the shielding portion 155 does not overlap with the via hole structures at a periphery of the shielding portion 155. The shielding portion 155 is used to shield the first conductor portion N51 (for example, a portion other than the region of the first via hole H151), which is beneficial to the signal shielding of the pixel circuit and enabling the layout space relatively more loose.

Similar to the display substrates illustrated in FIG. 11A-FIG. 11E, referring to FIG. 12E and FIG. 12I, the second connection layer LY4 includes an initialization connection signal line CON-Vinit with a different wiring trend, and the initialization connection signal line CON-Vinit extends along the first direction N. The second conductive layer LY2 includes a first initialization signal line INTL, and the first initialization signal line INT1 extends along the second direction Y. The plurality of transistors include a first reset transistor T1, the first electrode of the first reset transistor T1 is connected to the first initialization signal line INT1, and the first initialization signal line INT1 is connected to the initialization connection signal line CON-Vinit. The orthographic projection of the initialization connection signal line CON-Vinit on the base substrate at least partially overlaps with the orthographic projection of the first connection portion 151 on the base substrate, and the initialization connection signal line CON-Vinit covers the first connection portion 151 at the first via hole H151, thereby weakening the influence of the signal lines connected at the first via hole H151 from the signals around and above the first via hole H151.

For example, referring to FIG. 12D, FIG. 12E and FIG. 12I, the plurality of pixel circuits include a plurality of pixel circuit groups. Each pixel circuit group includes a first pixel circuit sub-group 162 and a second pixel circuit sub-group, the second pixel circuit sub-group and the first pixel circuit sub-group 162 are arranged sequentially along the second direction, the first pixel circuit sub-group 162 includes a plurality of first pixel circuit arranged sequentially along the first direction, the second pixel circuit sub-group includes a plurality of second pixel circuits and third pixel circuits arranged sequentially along the first direction, and the initialization connection signal line CON-Vinit is provided in the first pixel circuit sub-group 162 to facilitate the layout design and improve the display effect.

For example, the first pixel circuit sub-group 162 is configured to drive the green sub-pixel to emit light. The basic structures of the plurality of sub-pixel circuits are identical to each other, and the first pixel circuit sub-group 162 is taken as an example for description below. The initialization connection signal line CON-Vinit is provided in the first pixel circuit sub-group 162.

Referring to FIG. 12D, FIG. 12E and FIG. 12I, in addition to the first connection portion 151, the display substrate further includes a plurality of connection portions provided in the first connection layer LY3, that is, a connection portion 157, a connection portion 158, a connection portion 159, a connection portion 160, a connection portion 161, and a connection portion 163 provided in the second connection layer LY4, and the plurality of connection portions can connect the transistors in the display substrate.

Referring to FIG. 12D, FIG. 12E and FIG. 12I, the first electrode of the first reset transistor T1 is connected to one end of the connection portion 157 at a via hole H165, and the other end of the connection portion 157 is connected to the first initialization signal line INT1 at a via hole H166, so that the first electrode of the first reset transistor T1 is connected to the first initialization signal line INT1. One end of the connection portion 161 is connected to the first electrode of the data writing transistor T4 through a via hole H170, and the other end of the connection portion 161 is connected to the data line DT through a via hole H171, that is, the connection between the first electrode of the data writing transistor T4 and data line DT is achieved through the connection portion 161. The first electrode of the second light-emitting control transistor T5 is connected to the first voltage signal line VDD at a via hole H167 through the connection portion 159. One end of the connection portion 160 is connected to the second electrode of the first light-emitting control transistor T6 through a via hole H168, and the other end of the connection portion 160 is connected to the connection portion 163 in the second connection layer LY4 through a via hole H169, and is further connected to the first electrode E1 (not illustrated in the figures) of the light-emitting element through the via hole H169. That is, the connection portion 160 and the connection portion 163 are served as two intermediate transfer connector to connect the second electrode of the first light-emitting control transistor T6 and the first electrode E1 of the light-emitting element. The first electrode of the second reset transistor T7 is connected to one end of the connection portion 158 at a via hole H163, and the other end of the connection portion 158 is connected to the second initialization signal line INT2 at a via hole H164, so that the first electrode of the second reset transistor T7 is connected to the second initialization signal line INT2.

For example, the first voltage signal line VDD is provided in the first connection layer LY3, the first voltage signal line VDD extends along the first direction N, and the orthographic projection of the initialization connection signal line CON-Vinit on the base substrate at least partially overlaps with the orthographic projection of the first voltage signal line VDD on the base substrate.

Referring to FIG. 12D, FIG. 12E and FIG. 12I, in the first direction, the initialization connection signal line CON-Vinit is first connected to the first connection portion 151, then connected to the first voltage signal line VDD, and finally connected to the connection portion 157. According to FIG. 12I, the first voltage signal line VDD is spaced apart from the first connection portion 151 and does not overlap with the first connection portion 151, the portion of the initialization connection signal line CON-Vinit that does not overlap with the first connection portion 151 should cover the first voltage signal line VDD as much as possible, and the orthographic projection of the initialization connection signal line CON-Vinit on the base substrate at least partially overlaps with the orthographic projection of the first voltage signal line VDD on the base substrate. In this way, the initialization connection signal line CON-Vinit can reduce the interference of the first voltage signal line VDD on other signals.

For example, in some embodiments of the present disclosure, the display substrate includes at least one via hole, at least one inorganic layer 231, and at least one filling portion, the at least one via hole is configured to achieve connection between different layers of the pixel circuit, and the orthographic projection of the at least one via hole on the base substrate does not overlap with the orthographic projection of the first connection layer LY3 on the base substrate. The at least one inorganic layer 231 is provided between the first connection layer LY3 and the base substrate, and includes at least one hollowed-out region 232, the orthographic projection of the at least one hollowed-out region 232 on the base substrate does not overlap with the orthographic projection of the first connection layer LY3 on the base substrate, and the filling portion is configured to fill in the at least one hollowed-out region 232.

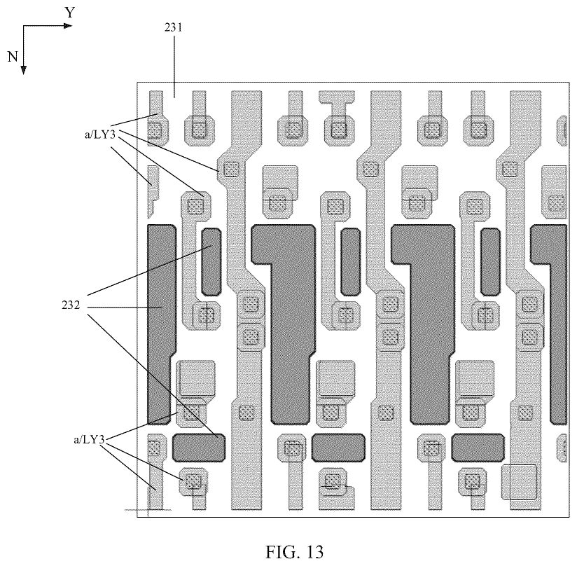

FIG. 13 is a schematic diagram of a hollowed-out region included in a display substrate provided by an embodiment of the present disclosure.

For example, referring to FIG. 10A-FIG. 10I and FIG. 13, the display substrate includes an active pattern layer LY0, a first conductive layer LY1, a second conductive layer LY2, a first connection layer LY3, and a fourth connection layer LY4 arranged sequentially on the base substrate. The stacking relationship and connection relationship between layers can refer to the relevant descriptions in the above embodiments, and details will not be repeated here.

It should be noted that an inorganic layer may be provided between any two layers of the active pattern layer LY0, the first conductive layer LY1, the second conductive layer LY2, the first connection layer LY3, and the fourth connection layer LY4 in the pixel circuit to insulate the respective layers and reduce the risk of circuit crosstalk.

In some embodiments, the display substrate may include at least one inorganic layer 231, and the at least one inorganic layer 231 includes a first inorganic layer ISL1, a second inorganic layer ISL2, a third inorganic layer ISL3, and a fourth inorganic layer ISL4.

For example, in the direction perpendicular to the base substrate and away from the base substrate, a buffer layer, an isolation layer, an active pattern layer LY0, a first inorganic layer ISL1, a first conductive layer LY1, a second inorganic layer ISL2, a second conductive layer LY2, a third inorganic layer ISL3, a first connection layer LY3, a fourth inorganic layer ISL4, a fourth connection layer LY4, etc., are provided sequentially on the base substrate, and each inorganic layer may be made of an inorganic material.

Referring to FIG. 10A-FIG. 10I and FIG. 13, each signal line and data line in the pixel circuit can be connected by penetrating respective inorganic layers, for example, each signal line and data line in the pixel circuit can be connected through at least one via hole, and the at least one via hole can penetrate the inorganic layer between adjacent connection layers to achieve connection. FIG. 13 illustrates the positional relationship of respective via holes, and the connection relationship of the respective via holes in the pixel circuit can refer to the description in the above-mentioned embodiments, which will not be repeated here.

For example, in FIG. 10A-FIG. 10I and FIG. 13, the at least one inorganic layer 231 includes at least one hollowed-out region 232, the orthographic projection of the at least one hollowed-out region 232 on the base substrate does not overlap with the orthographic projection of the first connection layer LY3 on the base substrate, and the filling portion is configured to fill in the at least one hollowed-out region 232. That is, the position of the hollowed-out region provided in the at least one inorganic layer 231 needs to avoid the pattern structure in the first connection layer LY3 and the position of the via hole connected to the first connection layer LY3, that is, a portion indicated by “a” in FIG. 13. In this way, the problem such as signal short circuit of the first connection layer LY3 can be avoided.

For example, in FIG. 10A-FIG. 10I and FIG. 13, the filling portion is provided inside each hollowed-out region 232. For example, the material of the filling portion may be different from the material of the inorganic layer.

For example, the filling portion may be made of an organic material. For example, organic materials with high insulation, high friction resistance, and high strength can be selected. For example, materials such as polyimide, etc. are adopted to improve the anti-extrusion performance of the display substrate and optimize the bending performance.

Another embodiment of the present disclosure provides a display device, including any one of the above-mentioned display substrates. The display device provided by the embodiments of the present disclosure enable the active patterns to form a plurality of units (a plurality of active sub-patterns) independent of each other by designing pixel circuits located in the display region and by performing a disconnection design on the active patterns in the pixel circuit, and connect the disconnected active patterns through connection components or perform signal input respectively, thereby effectively reducing the impact in process such as electrostatic discharge, etc., improving the display effect of the display substrate and improving the yield of the product. For example, the pixel circuit in the display substrate may also adopt other pixel circuits such as 5T1C or 8T1C, and the embodiments of the present disclosure are only illustrative, not restrictive, of the form of the pixel circuit.

For example, the display device provided by the embodiments of the present disclosure is an organic light emitting diode display device.

For example, the display device may further include a cover plate on the display side of the display substrate.

For example, the display device is any product or component with a display function such as a mobile phone, a tablet computer, a notebook computer, or a navigator with an under-screen camera, and the present embodiment is not limited thereto.

It should be noted that each of the transistors used in the embodiments of the present disclosure may be a thin film transistor, a field effect transistor or other switching component having the same characteristics. The source electrode and drain electrode of the transistor adopted here may be structurally symmetrical, so that the source electrode and the drain electrode may be structurally indistinguishable. In the embodiments of the present disclosure, in order to distinguish the two electrodes of the transistor except the control electrode (the gate electrode), one electrode is directly described as the first electrode, and the other electrode is described as the second electrode, so the first and second electrodes of all or part of the transistors in the embodiments of the present disclosure are interchangeable as required. For example, the first electrode of the transistor described in the embodiments of the present disclosure is the source electrode, and the second electrode is the drain electrode; or, the first electrode of the transistor is the drain electrode, and the second electrode is the source electrode.

In addition, the transistors can be divided into N-type and P-type transistors according to the characteristics of the transistors. The embodiments of the present disclosure are described by taking the case where the transistors all adopt P-type transistors as an example. Based on the description and teaching of this implementation in the present disclosure, those skilled in the art can easily think of adopting at least some transistors in the pixel circuit structure of the embodiments of the present disclosure as N-type transistors, that is, adopting N-type transistors or the combination of N-type transistors and P-type transistors without creative work. Therefore, these implementations are also within the protection scope of the present disclosure.

The following statements should be noted.

(1) The drawings involve only the structure(s) in connection with the embodiment(s) of the present disclosure, and other structure(s) can be referred to common design(s).

(2) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1: A display substrate, comprising:
a base substrate; and
a plurality of pixel circuits, wherein the plurality of pixel circuits are arranged on the base substrate in an array,
wherein the plurality of pixel circuits comprise a plurality of active patterns, each of the plurality of active patterns extends along a first direction, the plurality of active patterns are arranged along a second direction, adjacent active patterns are spaced apart from each other in the second direction, and at least one of the plurality of active patterns comprises at least one disconnection position to form a plurality of active sub-patterns independent of each other.

2: The display substrate according to claim 1, wherein two adjacent active sub-patterns are connected through a same connection portion at the disconnection position, and/or two adjacent active sub-patterns are respectively connected to two different signal lines at the disconnection position.

3: The display substrate according to claim 1, wherein the active pattern comprises a semiconductor region and a conductor region, and the disconnection position of the active pattern is located in the conductor region.

4. (canceled)

5: The display substrate according to claim 3, wherein each of the plurality of pixel circuits comprises transistors, and each of the transistors comprises a control electrode, a first electrode, and a second electrode, the semiconductor region is configured to form a channel region of the transistor corresponding to the control electrode, and the conductor region is configured to form the first electrode and the second electrode of the transistor.

6-8. (canceled)

9: The display substrate according to claim 5, further comprising a first connection layer,
wherein the first connection layer is provided on a side of the plurality of active patterns facing away from the base substrate, the first connection layer comprises a plurality of connection portions, and at least one of the plurality of connection portions is configured to connect the transistors.

10: The display substrate according to claim 9, wherein the conductor region comprises a first conductor portion, and the first conductor portion is disconnected and comprises a first disconnection end and a second disconnection end at the disconnection position,
the transistor comprises a first reset transistor and a threshold compensation transistor,
the first disconnection end is served as a second electrode of the first reset transistor, and the second disconnection end is served as a second electrode of the threshold compensation transistor, and
the plurality of connection portions comprise a first connection portion, and the first connection portion is configured to connect the first disconnection end of the first conductor portion and the second disconnection end of the first conductor portion,
wherein the transistors further comprise a driving transistor, and the first connection portion is connected to a control electrode of the driving transistor.

11. (canceled)

12: The display substrate according to claim 9, wherein the conductor region further comprises a second conductor portion, and the second conductor portion is disconnected and comprises a third disconnection end and a fourth disconnection end at the disconnection position,
the transistor further comprises a first light-emitting control transistor and a second reset transistor,
the third disconnection end is served as a second electrode of the first light-emitting control transistor, and the fourth disconnection end is served as a second electrode of the second reset transistor, and
the plurality of connection portions comprise a second connection portion, and the second connection portion is configured to connect the third disconnection end of the second conductor portion and the fourth disconnection end of the second conductor portion,
the display substrate further comprises a light-emitting element, wherein the second connection portion is connected to the light-emitting element, the third disconnection end, and the fourth disconnection end, respectively.

13. (canceled)

14: The display substrate according to claim 9, wherein the conductor region further comprises a third conductor portion, and the third conductor portion is disconnected and comprises a fifth disconnection end and a sixth disconnection end at the disconnection position,
the transistor further comprises a first reset transistor and a second reset transistor,
the fifth disconnection end is served as a first electrode of the first reset transistor, and the sixth disconnection end is served as a first electrode of the second reset transistor,
the display substrate further comprises a first conductive layer and a second conductive layer, and the plurality of active patterns, the first conductive layer, and the second conductive layer are provided sequentially along a direction away from the base substrate, and the plurality of connection portions comprise a fifth connection portion and a sixth connection portion, and
the second conductive layer comprises a first initialization signal line and a second initialization signal line, the first electrode of the first reset transistor is connected to the first initialization signal line through the fifth connection portion, and the first electrode of the second reset transistor is connected to the second initialization signal line through the sixth connection portion.

15: The display substrate according to claim 1, wherein at least one of the plurality of active patterns comprises adjacent disconnection positions spaced apart by at least one row of the pixel circuits.

16: The display substrate according to claim 1, wherein the amounts of the pixel circuits in at least two columns are not equal.

17: The display substrate according to claim 1,
wherein active patterns corresponding to at least one column of the pixel circuits are all provided with at least one disconnection position, and/or
active patterns corresponding to at least one row of the pixel circuits are all provided with at least one disconnection position,
wherein the active patterns corresponding to at least one column of the pixel circuits are all provided with at least one same disconnection position, and/or
the active patterns corresponding to at least one row of the pixel circuits are all provided with at least one same disconnection position.

18-19. (canceled)

20: The display substrate according to claim 9, wherein the transistor comprises a threshold compensation transistor, and the threshold compensation transistor is a single-gate transistor,
the display substrate further comprises a first conductive layer and a second conductive layer,
wherein the first conductive layer is located between the plurality of active patterns and the first connection layer, and a control electrode of the threshold compensation transistor is located in the first conductive layer,
the second conductive layer is located between the first conductive layer and the first connection layer, the second conductive layer comprises a first power supply signal line, and the first power supply signal line extends along the second direction, and
the transistor further comprises a driving transistor, and in the first direction, the first supply power signal line is located on a side of the control electrode of the threshold compensation transistor away from the driving transistor.

21: The display substrate according to claim 20, wherein the conductor region comprises a first conductor portion, the transistor further comprises a first reset transistor, and the first conductor portion is served as a second electrode of the first reset transistor and a second electrode of the threshold compensation transistor,
the first connection layer comprises a first connection portion, and a control electrode of the driving transistor is connected to the first conductor portion through the first connection portion at a first via hole, and
the first power supply signal line comprises a main body portion and at least one isolation portion, the main body portion extends along the second direction, the at least one isolation portion is connected to the main body portion and extends along the first direction, and the first via hole is located in a surrounded region formed by the at least one isolation portion and the main body portion.

22: The display substrate according to claim 21, wherein the first power supply signal line further comprises at least one shielding portion, the at least one shielding portion is connected to the main body portion and extends along the first direction, and the at least one shielding portion is provided on a side of the main body portion away from the isolation portion, and
an orthographic projection of the at least one shielding portion on the base substrate at least partially overlaps with an orthographic projection of the first conductor portion on the base substrate.

23: The display substrate according to claim 9, further comprising a first conductive layer and a second conductive layer,
wherein the first conductive layer, the second conductive layer, and the first connection layer are arranged sequentially along a direction away from the base substrate, the second conductive layer comprises a first power supply signal line, the first power supply signal line comprises a plurality of power supply portions, and the plurality of power supply portions are arranged along the second direction and spaced apart from each other,
the conductor region comprises a first conductor portion, the transistor further comprises a first reset transistor, a threshold compensation transistor, and a driving transistor, and the first conductor portion is served as a second electrode of the first reset transistor and a second electrode of the threshold compensation transistor, and
the plurality of connection portions comprise a first connection portion, a control electrode of the driving transistor is connected to the first conductor portion through the first connection portion at a first via hole, and the first via hole is located between adjacent power supply portions.

24: The display substrate according to claim 23, wherein each of the plurality of power supply portions comprises a main body portion and at least one isolation portion,
the at least one isolation portion is connected to the main body portion and extends along the first direction, and the first via hole is located between one main body portion and one isolation portion that are adjacent to each other.

25: The display substrate according to claim 9, further comprising a first conductive layer, a second conductive layer, and a second connection layer,
wherein the first conductive layer, the second conductive layer, and the second connection layer are arranged sequentially along a direction away from the base substrate,
the second connection layer is located on a side of the first connection layer away from the base substrate, the second connection layer comprises an initialization connection signal line, and the initialization connection signal line extends along the first direction,
the second conductive layer comprises a first initialization signal line, and the first initialization signal line extends along the second direction, and
the transistors comprise a first reset transistor, a first electrode of the first reset transistor is connected to the first initialization signal line, and the first initialization signal line is connected to the initialization connection signal line.

26: The display substrate according to claim 25, wherein the plurality of connection portions comprise a first connection portion,
the transistors further comprise a threshold compensation transistor and a driving transistor, and a second electrode of the first reset transistor, a second electrode of the threshold compensation transistor, and a control electrode of the driving transistor are connected to the first connection portion, and
an orthographic projection of the initialization connection signal line on the base substrate at least partially overlaps with an orthographic projection of the first connection portion on the base substrate.

27: The display substrate according to claim 20, wherein the first conductive layer comprises a first capacitor portion, the first capacitor portion comprises a plurality of first capacitor sub-portions, and the plurality of first capacitor sub-portions are spaced apart from each other along the second direction, and
the second conductive layer comprises a second capacitor portion, the second capacitor portion comprises a plurality of capacitor islands, the plurality of capacitor islands are spaced apart from each other, and each of the plurality of first capacitor sub-portions is provided opposite to at least part of one of the plurality of capacitor islands.

28: A display device, comprising the display substrate according to claim 1.
